(19) United States
(12) Patent Application Publication
(10) Pub. No.: US 2025/0024705 A1
(43) Pub. Date: Jan. 16, 2025

(54) DISPLAY SUBSTRATE, DISPLAY APPARATUS AND METHOD FOR MANUFACTURING DISPLAY SUBSTRATE

(71) Applicants: HEFEI XINSHENG OPTOELECTRONICS TECHNOLOGY CO., LTD., Hefei (CN); BOE TECHNOLOGY GROUP CO., LTD., Beijing (CN)

(72) Inventors: Liusong Ni, Beijing (CN); Cheng Xu, Beijing (CN); Chen Xu, Beijing (CN); Ce Zhao, Beijing (CN); Ming Wang, Beijing (CN); Yingbin Hu, Beijing (CN); Ning Liu, Beijing (CN); Jiawen Song, Beijing (CN); Junlin Peng, Beijing (CN); Wei He, Beijing (CN)

(21) Appl. No.: 18/701,887

(22) PCT Filed: Apr. 28, 2023
(86) PCT No.: PCT/CN2023/091837

§ 371 Date: Apr. 16, 2024

(30) Foreign Application Priority Data
May 24, 2022 (CN) 202210578148.8

(51) Int. Cl. H10K 59/121; H10K 59/12; H10K 59/123

(52) U.S. Cl. CPC H10K 59/1213; H10K 59/1201; H10K 59/123; H10K 59/1216

(57) ABSTRACT

A display substrate is provided, including: pixel units on a base substrate; and a first conductive layer, a buffer layer, a semiconductor layer, a first insulation layer, and a second conductive layer which are arranged on the base substrate in a direction away from the base substrate. The display substrate further includes at least one conductive via hole passing through at least the first insulation layer, and at least one conductive plug through which the second conductive portion is electrically connected to the first conductive portion. The first conductive portion includes first and second conductive sub-portions, an orthographic projection of the first conductive sub-portion on the base substrate at least partially overlaps with that of the at least one conductive via hole on the base substrate, and in a third direction, a thickness of the first conductive sub-portion is greater than that of the second conductive sub-portion.

### CROSS-REFERENCE TO RELATED APPLICATION

This application is a Section 371 National Stage Application of International Application No. PCT/CN2023/091837, filed Apr. 28, 2023, which claims priority to Chinese Patent Application No. 202210578148.8, filed May 24, 2022, the contents of which are incorporated herein by reference in their entirety.

### TECHNICAL FIELD

The present disclosure relates to the field of display technology, in particular to a display panel and a display apparatus.

### BACKGROUND

Organic light-emitting diode (OLED) display panels have the advantages of self-luminescence, good temperature characteristics, low power consumption, fast response, and bendability, and thus have gradually become one of the mainstream display technologies and are increasingly widely used in display apparatus such as mobile phones, computers, and televisions. In the design of the backboard of the OLED display panel, ensuring the transmittance of the light-emitting regions is one of the important topics for researchers in the art.

It will be noted that the information disclosed in the background section above is only intended to enhance the understanding of the background of the present disclosure, and thus may include information that does not constitute prior art known to those skilled in the art

### SUMMARY

In an aspect, a display substrate is provided, including:
a base substrate;
a plurality of pixel units provided on the base substrate, where the plurality of pixel units are arranged in an array in a first direction and a second direction, and at least one of the plurality of pixel units includes a plurality of sub-pixels, at least one of the plurality of sub-pixels includes a light-emitting element and a pixel driving circuit configured to drive the light-emitting element, the first direction intersecting with the second direction;
a first conductive layer provided on the base substrate;
a buffer layer provided on a side of the first conductive layer away from the base substrate;
a semiconductor layer provided on a side of the buffer layer away from the base substrate;
a first insulation layer provided on a side of the semiconductor layer away from the base substrate; and
a second conductive layer provided on a side of the first insulation layer away from the base substrate,
where the pixel driving circuit includes at least one transistor and a storage capacitor, the at least one transistor includes a source and a drain, the storage capacitor includes a first capacitor electrode and a second capacitor electrode opposite to each other, one of the first capacitor electrode and the second capacitor electrode is in the first conductive layer, and the source and the drain of the at least one transistor are in the second conductive layer;
where the display substrate includes a first conductive portion in the first conductive layer and a second conductive portion in the second conductive layer, and an orthographic projection of the first conductive portion on the base substrate at least partially overlaps with an orthographic projection of the second conductive portion on the base substrate;
where the display substrate further includes at least one conductive via hole and at least one conductive plug in the at least one conductive via hole, the at least one conductive via hole passing through at least the first insulation layer, and the second conductive portion is electrically connected to the first conductive portion through the at least one conductive plug; and
where the first conductive portion includes a first conductive sub-portion and a second conductive sub-portion, an orthographic projection of the first conductive sub-portion on the base substrate at least partially overlaps with an orthographic projection of the at least one conductive via hole on the base substrate, and a thickness of the first conductive sub-portion in a third direction is greater than a thickness of the second conductive sub-portion in the third direction, the third direction being perpendicular to a plane defined by the first direction and the second direction.

According to some exemplary embodiments, the first conductive sub-portion includes a first top surface away from the base substrate, the second conductive sub-portion includes a second top surface away from the base substrate, and the first top surface is further away from the base substrate than the second top surface in the third direction.

According to some exemplary embodiments, the first conductive sub-portion includes a protruding portion, the protruding portion protrudes towards the at least one conductive via hole relative to the second top surface of the second conductive sub-portion, and the at least one conductive plug is in contact with at least a part of the first top surface of the first conductive sub-portion.

According to some exemplary embodiments, the buffer layer exposes at least a part of the first conductive sub-portion; and/or, the buffer layer covers the second conductive sub-portion.

According to some exemplary embodiments, the buffer layer includes a third top surface away from the base substrate, and the first top surface of the first conductive sub-portion is substantially flush with a part of the third top surface adjacent to the first conductive sub-portion.

According to some exemplary embodiments, the protruding portion includes a first side surface and a second side surface, the first side surface and the second side surface are on opposite sides of the first top surface, and the first side surface and the second side surface is connected through the first top surface; and the buffer layer is in contact with a second top surface of the second conductive sub-portion, the first side surface and the second side surface, and the buffer layer covers the second top surface of the second conductive sub-portion, the first side surface and the second side surface.

According to some exemplary embodiments, the first conductive sub-portion includes a first bottom surface proximate to the base substrate, the second conductive sub-portion includes a second bottom surface proximate to the base substrate, and the first bottom surface is substantially flush with the second bottom surface in the third direction.

According to some exemplary embodiments, the second conductive portion includes a third bottom surface proximate to the base substrate; at a position adjacent to the at least one conductive via hole, the third bottom surface of the second conductive portion is spaced apart from the second top surface of the second conductive sub-portion by a first distance in the third direction, and a depth of the at least one conductive via hole in the third direction is less than the first distance.

According to some exemplary embodiments, the first conductive portion includes a first conductive connection portion in the first conductive layer, and at least a part of the first conductive connection portion serves as the second capacitor electrode; the second conductive portion includes a first conductive transfer portion in the second conductive layer; and an orthographic projection of the first conductive transfer portion on the base substrate falls within an orthographic projection of the first conductive connection portion on the base substrate.

According to some exemplary embodiments, the at least one conductive via hole includes a first conductive via hole, and the at least one conductive plug includes a first conductive plug in the first conductive via hole; the orthographic projection of the first conductive transfer portion on the base substrate at least partially overlaps with an orthographic projection of the first conductive via hole on the base substrate; and an orthographic projection of a part of the first conductive via hole on the base substrate at least partially overlaps with an orthographic projection of a first conductive sub-portion of the first conductive connection portion on the base substrate, one end of the first conductive plug is electrically connected to the first conductive sub-portion of the first conductive connection portion, and the other end of the first conductive plug is electrically connected to the first conductive transfer portion.

According to some exemplary embodiments, the at least one transistor includes a driving transistor, and the driving transistor includes a channel region; the display substrate further includes a first semiconductor portion in the semiconductor layer, the first semiconductor portion includes a first source region, a first drain region and the channel region of the driving transistor, and the first source region and the first drain region are on opposite sides of the channel region of the driving transistor, respectively; the orthographic projection of the first conductive via hole on the base substrate at least partially overlaps with an orthographic projection of one of the first source region and the first drain region on the base substrate; and the one of the first source region and the first drain region is electrically connected to the first conductive transfer portion through the first conductive via hole.

According to some exemplary embodiments, the first conductive portion includes a second conductive connection portion in the first conductive layer, the display substrate further includes a sensing signal line, and the second conductive connection portion is electrically connected to the sensing signal line; the second conductive portion includes a second conductive transfer portion in the second conductive layer; and where an orthographic projection of the second conductive transfer portion on the base substrate at least partially overlaps with an orthographic projection of the second conductive connection portion on the base substrate.

According to some exemplary embodiments, the at least one conductive via hole includes a second conductive via hole, and the at least one conductive plug includes a second conductive plug in the second conductive via hole; the orthographic projection of the second conductive transfer portion on the base substrate at least partially overlaps with an orthographic projection of the second conductive via hole on the base substrate; where an orthographic projection of a part of the second conductive via hole on the base substrate at least partially overlaps with an orthographic projection of a first conductive sub-portion of the second conductive connection portion on the base substrate, one end of the second conductive plug is electrically connected to the first conductive sub-portion of the second conductive connection portion, and the other end of the second conductive plug is electrically connected to the second conductive transfer portion.

According to some exemplary embodiments, the at least one transistor includes a sensing transistor, and the sensing transistor includes a channel region; the display substrate further includes a third semiconductor portion in the semiconductor layer, the third semiconductor portion includes a third source region, a third drain region and the channel region of the sensing transistor, and the third source region and the third drain region are on opposite sides of the channel region of the sensing transistor, respectively; the orthographic projection of the second conductive via hole on the base substrate at least partially overlaps with an orthographic projection of one of the third source region and the third drain region on the base substrate; and the one of the third source region and the third drain region is electrically connected to the second conductive transfer portion through the second conductive via hole.

According to some exemplary embodiments, the first conductive portion includes a third conductive connection portion in the first conductive layer; the second conductive portion includes a third conductive transfer portion in the second conductive layer, the display substrate includes a first power signal line in the second conductive layer, and the third conductive connection portion is a part of the first power signal line; and an orthographic projection of the third conductive transfer portion on the base substrate at least partially overlaps with an orthographic projection of the third conductive connection portion on the base substrate.

According to some exemplary embodiments, the at least one conductive via hole includes a third conductive via hole, and the at least one conductive plug includes a third conductive plug in the third conductive via hole; an orthographic projection of the first power signal line on the base substrate at least partially overlaps with an orthographic projection of the third conductive via hole on the base substrate; and the third conductive connection portion includes two first conductive sub-portions, the orthographic projection of the third conductive via hole on the base substrate at least partially overlaps with an orthographic projection of one of the two first conductive sub-portions of the third conductive connection portion on the base substrate, one end of the third conductive plug is electrically connected to one of the two first conductive sub-portions of the third conductive connection portion, and the other end of the third conductive plug is electrically connected to the first power signal line.

According to some exemplary embodiments, the second conductive portion further includes a fourth conductive transfer portion in the second conductive layer; and an orthographic projection of the fourth conductive transfer portion on the base substrate at least partially overlaps with the orthographic projection of the third conductive connection portion on the base substrate.

According to some exemplary embodiments, the at least one conductive via hole includes a fourth conductive via hole, and the at least one conductive plug includes a fourth conductive plug in the fourth conductive via hole; the orthographic projection of the fourth conductive transfer portion on the base substrate at least partially overlaps with an orthographic projection of the fourth conductive via hole on the base substrate; and the orthographic projection of the fourth conductive via hole on the base substrate at least partially overlaps with an orthographic projection of the other one of the two first conductive sub-portions of the third conductive connection portion on the base substrate, one end of the fourth conductive plug is electrically connected to the other one of the two first conductive sub-portions of the third conductive connection portion, and the other end of the fourth conductive plug is electrically connected to the fourth conductive transfer portion.

According to some exemplary embodiments, the first conductive portion includes a fourth conductive connection portion in the first conductive layer; the second conductive portion includes a fifth conductive transfer portion in the second conductive layer; and an orthographic projection of the fifth conductive transfer portion on the base substrate at least partially overlaps with an orthographic projection of the fourth conductive connection portion on the base substrate.

According to some exemplary embodiments, the at least one conductive via hole includes a fifth conductive via hole, and the at least one conductive plug includes a fifth conductive plug in the fifth conductive via hole; the orthographic projection of the fifth conductive transfer portion on the base substrate at least partially overlaps with an orthographic projection of the fifth conductive via hole on the base substrate; and the orthographic projection of the fifth conductive via hole on the base substrate at least partially overlaps with an orthographic projection of a first conductive sub-portion of the fourth conductive connection portion on the base substrate, one end of the fifth conductive plug is electrically connected to the first conductive sub-portion of the fourth conductive connection portion, and the other end of the fifth conductive plug is electrically connected to the fifth conductive transfer portion.

According to some exemplary embodiments, the orthographic projection of the fifth conductive via hole on the base substrate at least partially overlaps with an orthographic projection of the other one of the third source region and the third drain region on the base substrate; and the other one of the third source region and the third drain region is electrically connected to the fifth conductive transfer portion through the fifth conductive via hole.

In another aspect, a display apparatus is provided, including the above-mentioned display substrate.

In yet another aspect, a method for manufacturing a display substrate is provided, including:
forming a first conductive material layer on a base substrate;
patterning the first conductive material layer using a halftone mask process to form a first conductive layer including a first conductive portion, where the first conductive portion includes a first conductive sub-portion and a second conductive sub-portion;
forming a buffer material layer on a side of the first conductive layer away from the base substrate;
patterning the buffer material layer using a mask process to form a buffer layer;
forming a semiconductor material layer on a side of the buffer layer away from the base substrate;
patterning the semiconductor material layer using a mask process to form a semiconductor layer;
forming a first insulation material layer on a side of the semiconductor layer away from the base substrate;
patterning the first insulation material layer using a mask process to form a first insulation layer including at least one conductive via hole, where the at least one conductive via hole passes through at least the first insulation layer;
forming a second conductive material layer on a side of the first insulation layer away from the base substrate, where at least a part of the second conductive material layer is formed in the at least one conductive via hole to form at least one conductive plug in the at least one conductive via hole; and
patterning the second conductive material layer using a mask process to form a second conductive layer including a second conductive portion, where an orthographic projection of the first conductive portion on the base substrate at least partially overlaps with an orthographic projection of the second conductive portion on the base substrate, and the second conductive portion is electrically connected to the first conductive portion through the at least one conductive plug,
where an orthographic projection of the first conductive sub-portion on the base substrate at least partially overlaps with an orthographic projection of the at least one conductive via hole on the base substrate, and a thickness of the first conductive sub-portion in a third direction is greater than a thickness of the second conductive sub-portion in the third direction, the third direction being perpendicular to a surface of the base substrate proximate to the first conductive layer.

### BRIEF DESCRIPTION OF THE DRAWINGS

Through the following description of the present disclosure with reference to the accompanying drawings, other objectives and advantages of the present disclosure will be apparent and may help to have a comprehensive understanding of the present disclosure.

FIG. 1 is a planar schematic diagram of a display substrate according to an embodiment of the present disclosure.

FIG. 2 is an equivalent circuit diagram of a pixel circuit for a single sub-pixel in the display substrate shown in FIG. 1.

FIGS. 3 to 13 are local plan views of at least one film layer of a display substrate according to some exemplary embodiments of the present disclosure, respectively, where FIG. 3 schematically shows a local plan view of a fourth conductive layer of the display substrate, FIG. 4 schematically shows a local plan view of a first conductive layer of the display substrate, FIG. 5 schematically shows a local plan view of a combination of the first conductive layer and the fourth conductive layer of the display substrate, FIG. 6 schematically shows a local plan view of a semiconductor layer of the display substrate, FIG. 7 schematically shows a local plan view of a combination of the fourth conductive layer, the first conductive layer and the semiconductor layer of the display substrate, FIG. 8 schematically shows a local plan view of a third conductive layer of the display substrate, FIG. 9 schematically shows a local plan view of a combination of the fourth conductive layer, the first conductive layer, the semiconductor layer and the third conductive layer of the display substrate, FIG. 10 schematically shows a local plan view of a combination of the fourth conductive layer, the first conductive layer, the semiconductor layer, the third conductive layer and the first insulation layer of the display substrate, FIG. 11 schematically shows a local plan view of a combination of the fourth conductive layer, the first conductive layer, the semiconductor layer, the third conductive layer, the first insulation layer and the second insulation layer of the display substrate, FIG. 12 schematically shows a local plan view of a second conductive layer of the display substrate, and FIG. 13 schematically shows a local plan view of a combination of the fourth conductive layer, the first conductive layer, the semiconductor layer, the third conductive layer, the first insulation layer, the second insulation layer and the second conductive layer of the display substrate.

FIG. 14 is a cross-sectional view of a display substrate taken along line AA′ in FIG. 13, according to some exemplary embodiments of the present disclosure.

FIGS. 15A to 15D are cross-sectional views of a display substrate taken along lines BB′, CC′, DD′ and EE′ in FIG. 4, respectively, according to some exemplary embodiments of the present disclosure.

FIGS. 16A to 16D are cross-sectional views of a display substrate taken along lines FF′, GG′, HH′ and II′ in FIG. 13, respectively, according to some exemplary embodiments of the present disclosure, where only electrical connections between a first conductive layer and a second conductive layer are shown, and other components are omitted.

FIG. 17 is a cross-sectional view of a display substrate taken along line JJ′ in FIG. 13, according to some exemplary embodiments of the present disclosure.

It will be noted that for clarity, the dimensions of layers, structures, or regions may be enlarged or reduced in the drawings used to describe the embodiments of the present disclosure, that is, these drawings are not drawn to actual scales.

### DETAILED DESCRIPTION OF EMBODIMENTS

Hereinafter, further specific explanations of the technical solution of the present disclosure will be provided through embodiments in conjunction with the accompanying drawings. In the specification, the same or similar reference numbers indicate the same or similar components. The following explanation of the embodiments of the present disclosure with reference to the accompanying drawings is intended to explain the overall inventive concept of the present disclosure and should not be understood as a limitation of the present disclosure.

In addition, in the following detailed description, for ease of explanation, many specific details are elaborated to provide a comprehensive understanding of the embodiments of the present disclosure. However, it is evident that one or more embodiments may also be implemented without these specific details.

It will be understood that, although the terms “first”, “second”, etc. may be used here to describe different elements, these elements should not be limited by these terms. These terms are only used to distinguish one element from another. For example, without departing from the scope of exemplary embodiments, the first element may be named the second element, and similarly, the second element may be named the first element. The term “and/or” used here includes any combination and all combinations of one or more related listed items.

In will be understood that, when an element or a layer is referred to as “formed on” a further element or layer, the element or layer may be directly or indirectly formed on the further clement or layer. That is to say, for example, there may be an intermediate element or intermediate layer. On the contrary, when an element or a layer is referred to as “directly formed on” a further element or layer, there is no intermediate element or intermediate layer. Other words used to describe the relationship between elements or layers will be explained in a similar way (such as “between” and “directly between”, “adjacent” and “directly adjacent”, etc.).

In this specification, directional expressions such as “first direction” and “second direction” are used to describe different directions of pixel arrangements, such as the horizontal and vertical directions of pixel arrangements. It will be understood that such expression is only an illustrative description and not a limitation on the present disclosure.

In this specification, unless otherwise specified, the expression “located in the same layer” generally means that the first and second components may be formed using the same material and through the same patterning process. The expression “A and B are connected as one” indicates that the component A and the component B are formed as one, that is, they usually contain the same material and form a whole component that is structurally continuous.

The transistors used in the embodiments of the present disclosure may all be thin film transistors, field-effect transistors, or other devices with same properties. Since the source and the drain of the thin film transistor used here are symmetrical, the source and the drain may be interchanged. In the following examples, the case where a P-type thin film transistor is used as a driving transistor is mainly described, while other transistors may have types the same as or different from the driving transistor according to the circuit design. Similarly, in other embodiments, the driving transistor may also be represented as an N-type thin film transistor.

Some exemplary embodiments of the present disclosure provide a display substrate, including: a base substrate; a plurality of pixel units on the base substrate, where the plurality of pixel units are arranged in an array along a first direction and a second direction, at least one pixel unit includes a plurality of sub-pixels, and at least one sub-pixel includes a light-emitting element and a pixel driving circuit for driving the light-emitting element; a semiconductor layer on the base substrate; a first conductive layer on a side of the semiconductor layer proximate to the base substrate; a second conductive layer on a side of the semiconductor layer away from the base substrate; and a pixel defining layer on a side of the second conductive layer away from the base substrate, where the pixel defining layer includes a plurality of openings for defining light-emitting regions of the plurality of sub-pixels, the pixel driving circuit includes a sensing transistor, a storage capacitor and a capacitor wire, the sensing transistor includes a source and a drain, the storage capacitor includes a first capacitor electrode and a second capacitor electrode opposite to each other, the capacitor wire is used to electrically connect one of the source and the drain of the sensing transistor to the second capacitor electrode; the source and the drain of the sensing transistor are located in the second conductive layer, the second capacitor electrode and the capacitor wire are both located in the first conductive layer, and the capacitor wire includes a capacitor wire main body portion extending along the second direction; and for the sub-pixel, an orthographic projection of the capacitor wire main body portion of the pixel driving circuit of the sub-pixel on the base substrate and the orthographic projection of the light-emitting region of the sub-pixel on the base substrate are spaced apart from each other. In the embodiments of the present disclosure, by arranging most of the capacitor wire (such as the capacitor wire main body portion) outside the light-emitting region of the sub-pixel, the shielding, by the capacitor wire, on the light emitted from the light-emitting region may be reduced, so that a light transmittance of the light-emitting region may be improved. In this way, the display quality of the display substrate may be improved without affecting the driving of the sensing transistor.

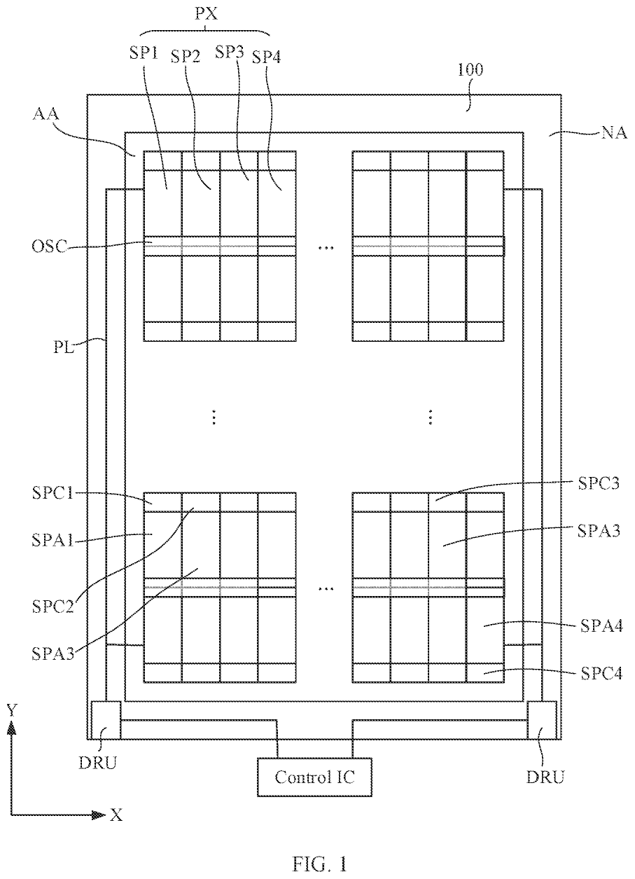

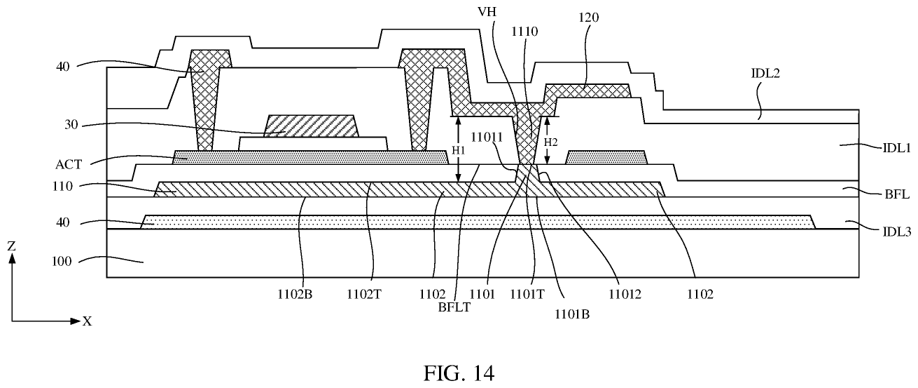

FIG. 1 is a planar schematic diagram of a display substrate according to an embodiment of the present disclosure. FIG. 14 is a local plan view of a display substrate according to some exemplary embodiments of the present disclosure, schematically illustrating more specific structures of the display substrate. Referring to FIGS. 1 and 14, a display substrate according to an embodiment of the present disclosure may include a base substrate 100, pixel units PX provided on the base substrate 100, driving units DRU provided on the base substrate 100, and wires PL electrically connecting the pixel units PX to the driving units DRU. The driving unit DRU is used to drive the pixel unit PX.

The display substrate may include a display area AA and a non-display area NA. The display area AA may be an area provided with pixel units PX for displaying images. The pixel units PX may be described later. The non-display area NA is a region with no pixel units PX provided therein, that is, it may be a region not for displaying images. The driving units DRU used to drive the pixel units PX and some wires PL connecting the pixel units PX to the driving units DRU may be provided in the non-display area NA. The non-display area NA corresponds to the bezel in the final DISPLAY APPARATUS, and a width of the bezel may be determined based on a width of the non-display area NA.

The display area AA may have various shapes. For example, the display area AA may be arranged in various shapes, such as a closed-shaped polygon including straight edges (for example, a rectangle), a circle or an ellipse including a curved edge, or a semicircle or semi ellipse including both a straight edge and a curved edge. In the embodiments of the present disclosure, the display area AA is provided as an area having a shape of a quadrilateral including straight edges. It will be understood that this is only an exemplary embodiment of the present disclosure and is not a limitation to the present disclosure.

The non-display area NA may be arranged on at least one side of the display area AA. In the embodiments of the present disclosure, the non-display area NA may surround a periphery of the display area AA. In the embodiments of the present disclosure, the non-display area NA may include a horizontal part extending in the first direction X and a vertical part extending in the second direction Y.

The pixel units PX are provided in the display area AA. The pixel unit PX is the smallest unit used to display images, and a plurality of pixel units may be provided. For example, the pixel unit PX may include light-emitting devices that emit white light and/or colored light.

The plurality of pixel units PX may be provided and arranged in a matrix including rows extending in the first direction X and columns extending in the second direction Y. However, in the embodiments of the present disclosure, the arrangement form of the pixel units PX is not specifically limited, and the pixel units PX may be arranged in various forms. For example, the pixel units PX may be arranged so that a direction inclined relative to both the first direction X and the second direction Y becomes a column direction, and a direction intersecting with the column direction becomes a row direction.

The pixel unit PX may include a plurality of sub-pixels. For example, the pixel unit PX may include three sub-pixels, namely a first sub-pixel SP1, a second sub-pixel SP2, and a third sub-pixel SP3. For another example, the pixel unit PX may include four sub-pixels, namely a first sub-pixel SP1, a second sub-pixel SP2, a third sub-pixel SP3, and a fourth sub-pixel SP4. For example, the first sub-pixel SP1 may be a red sub-pixel, the second sub-pixel SP2 may be a green sub-pixel, the third sub-pixel SP3 may be a blue sub-pixel, and the fourth sub-pixel SP4 may be a white sub-pixel.

Each sub-pixel may include a light-emitting element and a pixel driving circuit for driving the light-emitting element. For example, the first sub-pixel SP1 may include a first light-emitting element located in a first light-emitting region SPA1 and a first pixel driving circuit SPC1 for driving the first light-emitting element, where the first light-emitting element may emit red light. The second sub-pixel SP2 may include a second light-emitting clement located in a second light-emitting region SPA2 and a second pixel driving circuit SPC2 for driving the second light-emitting element, where the second light-emitting clement may emit green light. The third sub-pixel SP3 may include a third light-emitting element located in a third light-emitting region SPA3 and a third pixel driving circuit SPC3 for driving the third light-emitting element, where the third light-emitting element may emit blue light. The fourth sub-pixel SP4 may include a fourth light-emitting element located in a fourth light-emitting region SPA4 and a fourth pixel driving circuit SPC4 for driving the fourth light-emitting element.

The light-emitting region of the sub-pixel may refer to a region where the light-emitting element of the sub-pixel is located. For example, in an OLED display substrate, the light-emitting element of the sub-pixel may include a stack of a first electrode (such as an anode), a light-emitting material layer, and a second electrode (such as a cathode). In this way, the light-emitting region of the sub-pixel may be a region corresponding to the light-emitting material layer sandwiched by the anode and the cathode. For another example, in the OLED display substrate, the display substrate may include a pixel defining layer on the base substrate 100, the pixel defining layer may include a plurality of openings corresponding to the plurality of sub-pixels, and the plurality of openings define the light-emitting regions of the plurality of sub-pixels, respectively.

The sub-pixel further includes a non-light-emitting region. For example, a part of the pixel driving circuit of the sub-pixel is located in the non-light-emitting region of the sub-pixel. A ratio of an area of the light-emitting region of each sub-pixel to an overall area of the sub-pixel (a sum of an area of the light-emitting region and an area of the non-light-emitting region) determines an aperture ratio of the sub-pixel.

The light-emitting device (such as a light-emitting layer, abbreviated as an EL layer) of OLED may not have good consistency during the fabrication. For example, when an evaporation process is used to fabricate the EL layer, the limitations of the evaporation process may result in inconsistent EL layers of the fabricated sub-pixels, leading to uneven luminance or uneven chromaticity between different sub-pixels. Moreover, as the usage time increases, the EL layers may experience varying degrees of aging, which may also lead to inconsistent EL layers of sub-pixels, resulting in uneven luminance or uneven chromaticity between different sub-pixels. In an embodiment of the present disclosure, the display substrate may further include a photosensitive circuit OSC, which may sense light actually emitted by the pixel unit. In this way, in the embodiments of the present disclosure, the display substrate may perform optical compensation on the sub-pixels within each pixel unit based on the light, actually emitted by the pixel unit, sensed by the photosensitive circuit OSC, so as to improve the uniformity of light emitting of the display substrate.

For example, in some exemplary embodiments of the present disclosure, each pixel unit PX is provided with a photosensitive circuit OSC. Each photosensitive circuit OSC senses the light actually emitted by the pixel unit PX.

For example, in an embodiment of the present disclosure, at least two pixel units PX may share one photosensitive circuit OSC. In pixel units located in a same column, two pixel units PX located in two rows adjacent to each other may share one photosensitive circuit OSC. In this way, there is no need to provide a photosensitive circuit for each pixel unit PX, so that the number of photosensitive circuits may be reduced and the aperture ratio may be improved.

When the display substrate is in a display state, the photosensitive circuit OSC may sense the light actually emitted by the two pixel units adjacent to the photosensitive circuit OSC. For example, the photosensitive circuit OSC may include at least a photoelectric conversion element. In this way, the photosensitive circuit OSC may be used to: sense the light actually emitted by the two pixel units adjacent to the photosensitive circuit OSC; and transmit a sensing electrical signal based on the sensed light.

For another example, referring to FIG. 1, the photosensitive circuit OSC may transmit the sensing electrical signal to an external circuit, such as a control IC of a display apparatus. The control IC may control a control signal transmitted to the pixel unit PX based on the sensing electrical signal, for example, may control a data signal transmitted to the pixel driving circuit of each sub-pixel. Under the control of the data signal, each sub-pixel emits light accordingly.

In the embodiment shown in FIG. 1, the sub-pixels SP1, SP2, SP3 and SP4 are provided side by side. Each of the sub-pixels SP1, SP2, SP3 and SP4 may have a respective data line DL.

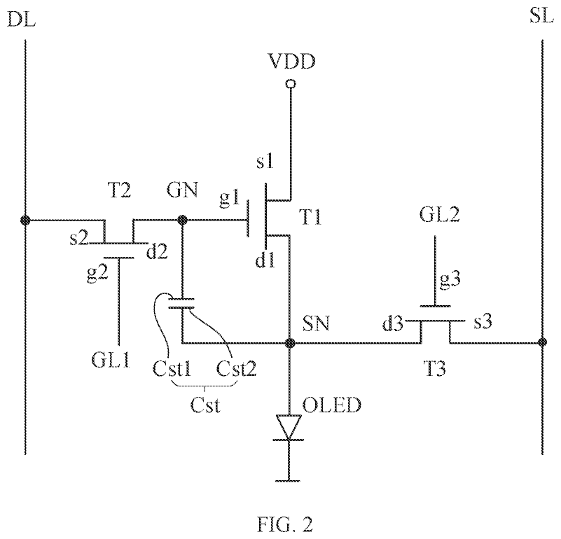

FIG. 2 is an equivalent circuit diagram of a pixel circuit for a single sub-pixel of the display substrate in FIG. 1. The pixel driving circuit shown in FIG. 2 may be any of the pixel driving circuits SPC1, SPC2, SPC3 and SPC4 mentioned above. Referring to FIG. 2, the pixel driving circuit may include a plurality of elements such as a driving transistor T1, a switching transistor T2, a sensing transistor T3, and a storage capacitor Cst. The pixel driving circuit may be referred to as a 3TIC structure.

It will be noted that the 3TIC structure is used as an example here to explain the pixel driving circuits in the display substrate according to the embodiments of the present disclosure. However, the pixel driving circuits in the display substrate of the embodiments of the present disclosure are not limited to the 3TIC structure.

Referring to FIG. 2, a gate g2 of the switching transistor T2 is electrically connected to a first scanning signal line GL1. A first electrode of the switching transistor T2 is electrically connected to a data line DL. A second electrode of the switching transistor T2 is electrically connected to a gate g1 of the driving transistor T1. For example, both the second electrode of the switching transistor T2 and the gate g1 of the driving transistor T1 may be electrically connected to a node GN. The switching transistor T2 is used to control the writing of the voltage signal from the data line DL into the pixel driving circuit.

It will be noted that each transistor may include an active layer, a gate, a first electrode (such as a source), and a second electrode (such as a drain). For example, the switching transistor T2 includes a gate g2 and an active layer ACT2. The driving transistor T1 includes a gate g1 and an active layer ACT1. The sensing transistor T3 includes a gate g3 and an active layer ACT3. In the embodiments of the present disclosure, the active layers of the transistors may be provided in the semiconductor layer, and the gates of the transistors may be provided in a conductive layer on a side of the semiconductor layer away from the base substrate.

It will be noted that in the present disclosure, a first electrode of a transistor may refer to one of a source (such as s1, s2, and s3) and a drain (such as d1, d2, and d3) of the transistor, and a second electrode of the transistor may refer to the other of the source (such as s1, s2, and s3) and the drain (such as d1, d2, and d3) of the transistor.

The gate g1 of the driving transistor T1 is electrically connected to the node GN. The first electrode of the driving transistor T1 is electrically connected to a first power signal (such as a high voltage level signal VDD). The second electrode of the driving transistor T1 may be electrically connected to an anode of the light-emitting element OLED, so that a driving current may be generated according to the voltage signal to drive the light-emitting element OLED to emit light. For example, the light-emitting element OLED may be an organic light-emitting diode (OLED).

Two terminals of the storage capacitor Cst are electrically connected to the gate g1 and the drain d1 of the driving transistor T1 respectively, so as to store the voltage signal transmitted from the data line DL. For example, one terminal of the storage capacitor Cst is electrically connected to the node GN, and the other terminal of the storage capacitor Cst is electrically connected to a node SN. For example, the storage capacitor Cst may include a first capacitor electrode Cst1 and a second capacitor electrode Cst2. The first capacitor electrode Cst1 of the storage capacitor Cst, the second electrode (such as the drain d2) of the switching transistor T2 and the gate g1 of the driving transistor T1 are all electrically connected to the node GN. The second capacitor electrode Cst2 of the storage capacitor Cst, the second electrode (such as the drain d1) of the driving transistor T1, and the anode of the light-emitting element OLED are all electrically connected to the node SN.

The gate g3 of the sensing transistor T3 is electrically connected to the second scanning signal line GL2, the first electrode (such as the source s3) of the sensing transistor T3 is electrically connected to a sensing signal line SL, and the second electrode (such as the drain d3) of the sensing transistor T3 is electrically connected to the node SN. That is, the second capacitor electrode Cst2 of the storage capacitor Cst, the second electrode (such as the drain d1) of the driving transistor T1, the anode of the light-emitting element OLED, and the second electrode (such as the drain d3) of the sensing transistor T3 are all electrically connected to the node SN.

The anode of the light-emitting element OLED is electrically connected to the node SN. The cathode of the light-emitting element OLED is electrically connected to a second power signal (such as a low voltage level signal VSS). Each of the level signals VDD and VSS is a DC voltage signal used to provide a desired voltage for driving the light-emitting element OLED to emit light.

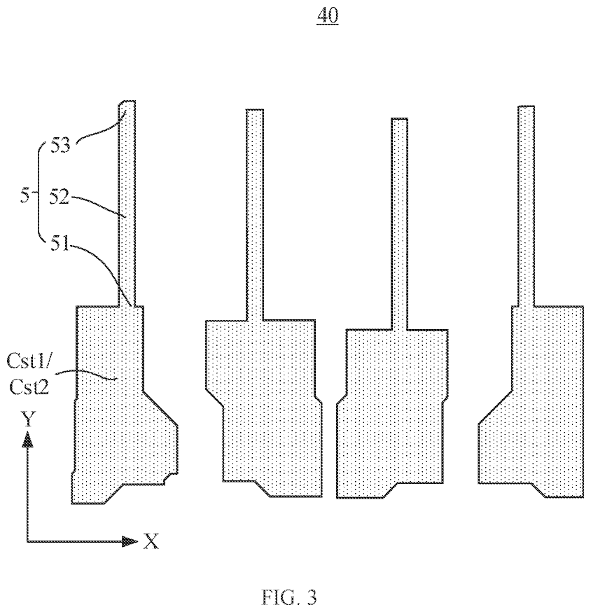

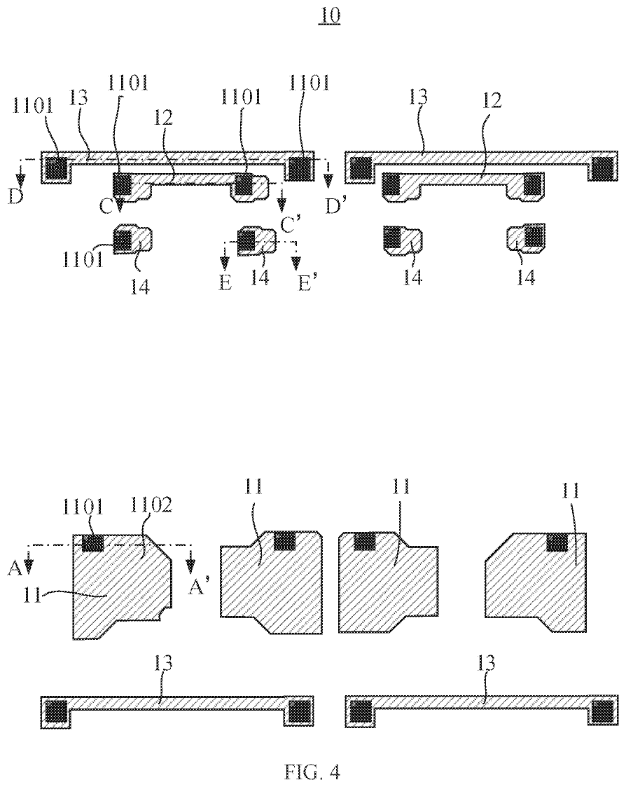

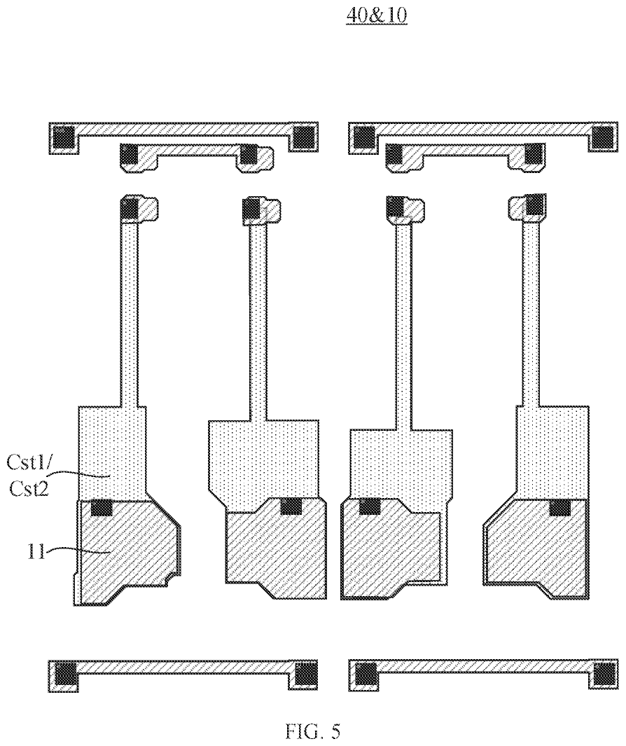

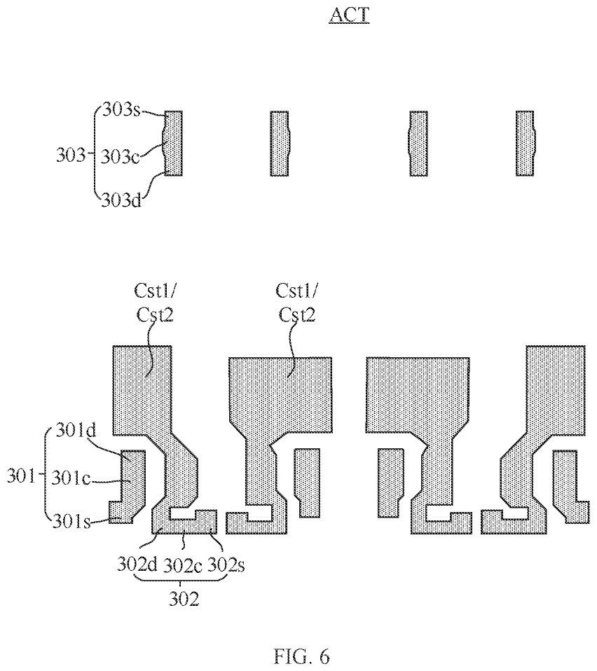

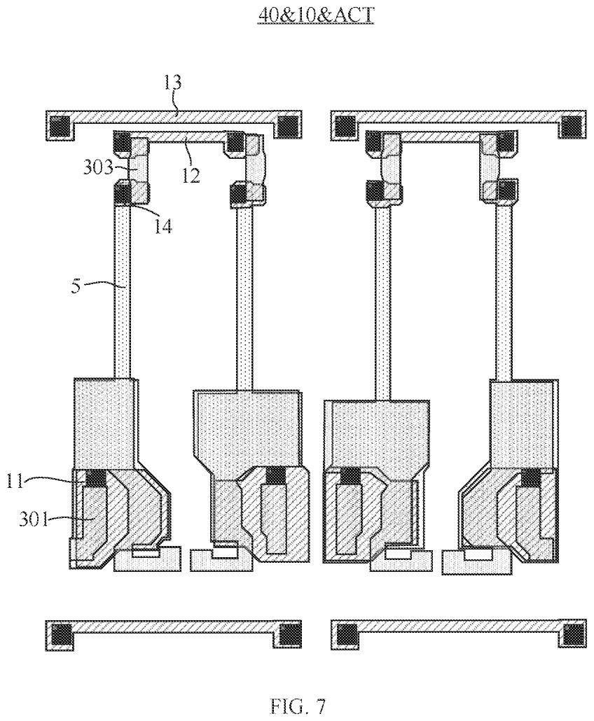

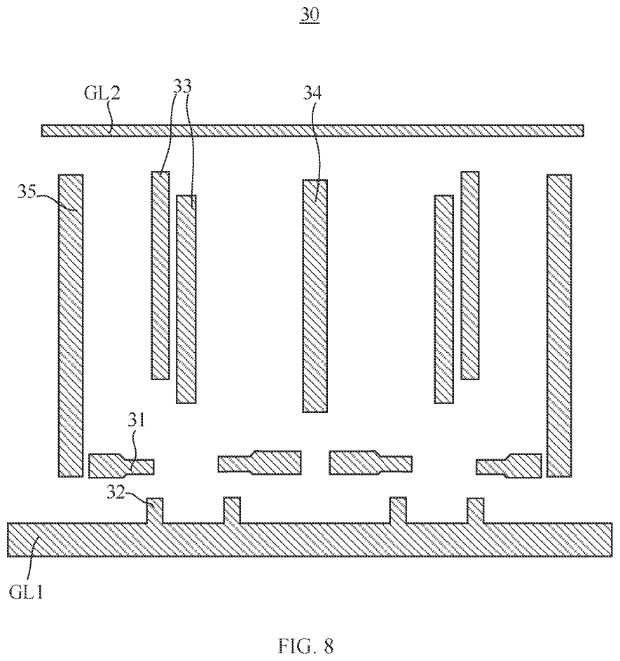

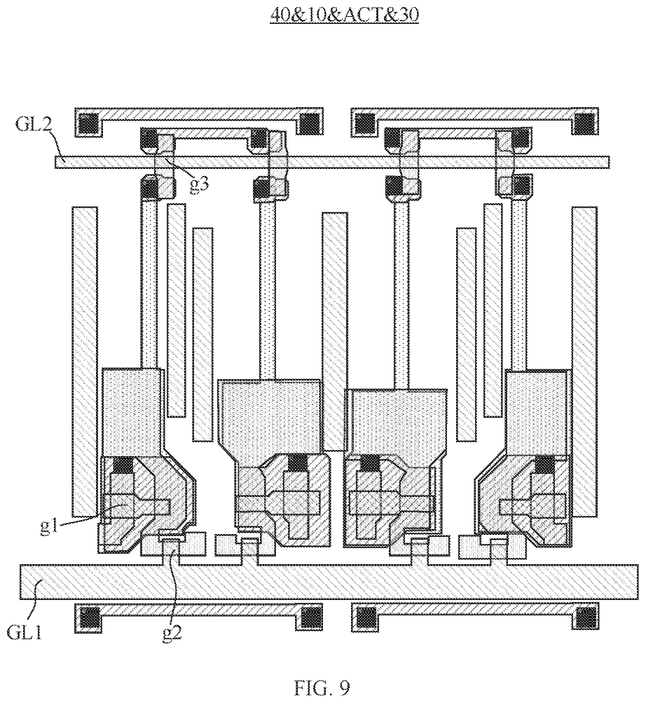

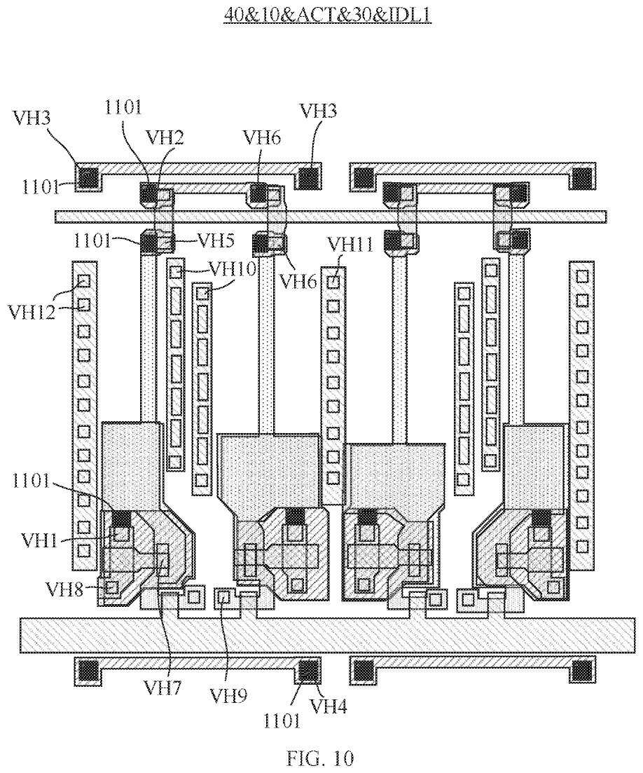

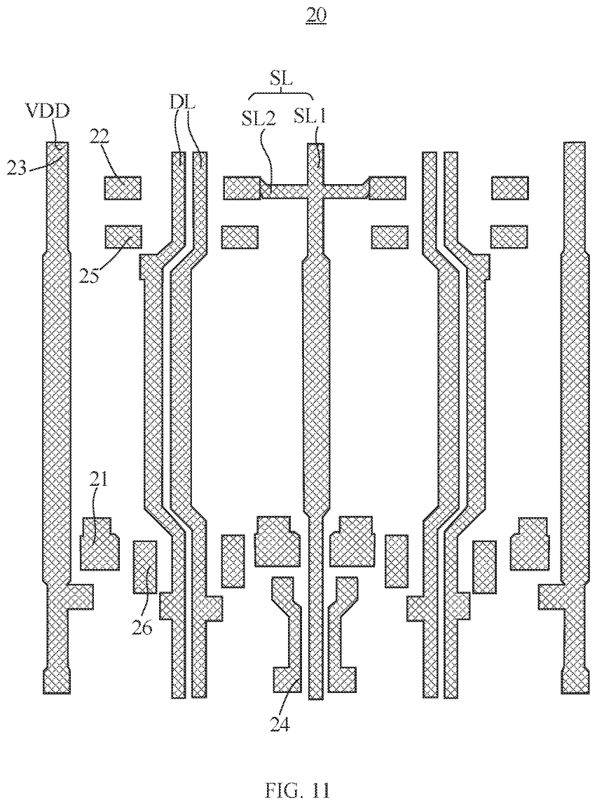

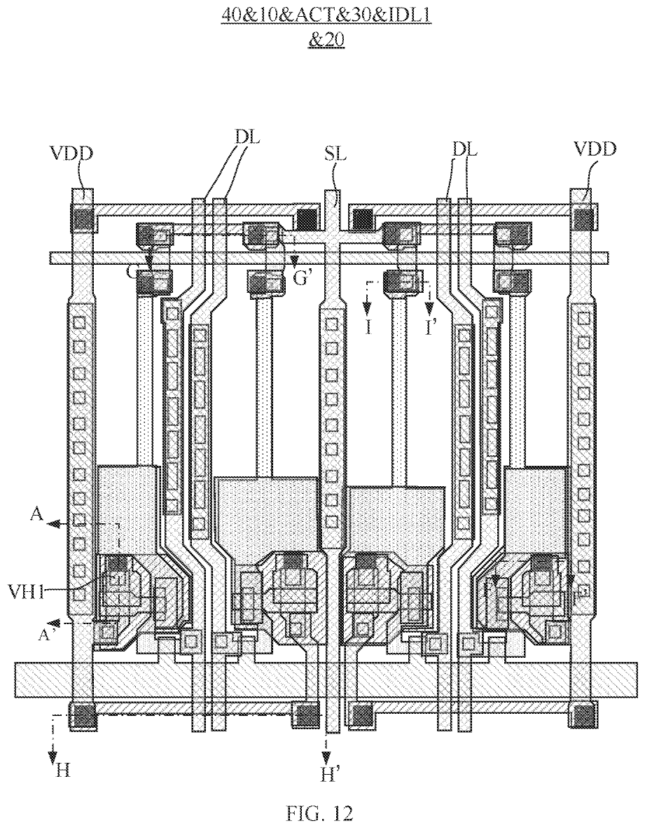

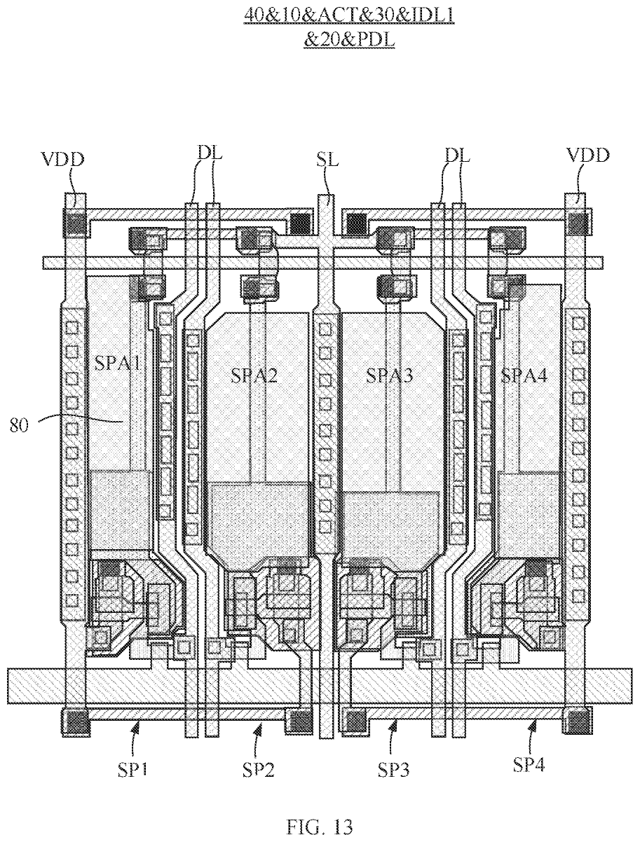

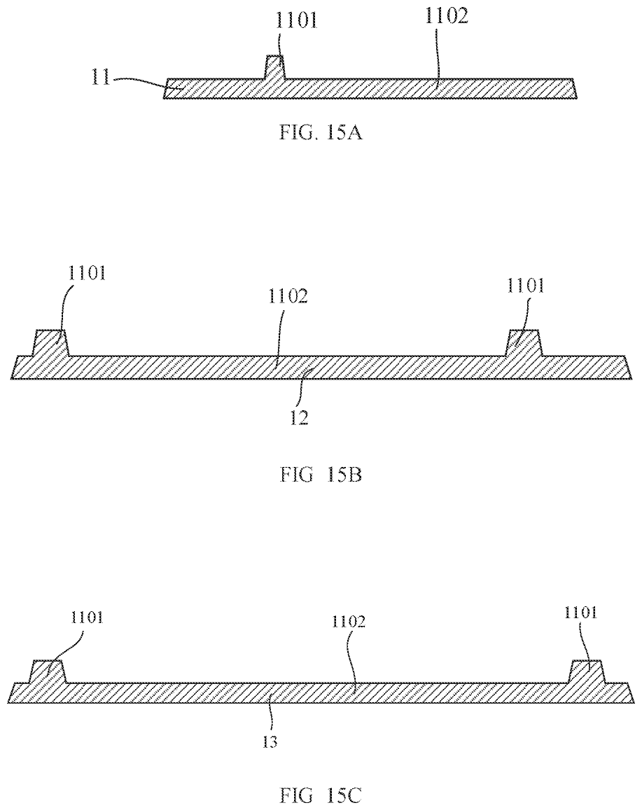

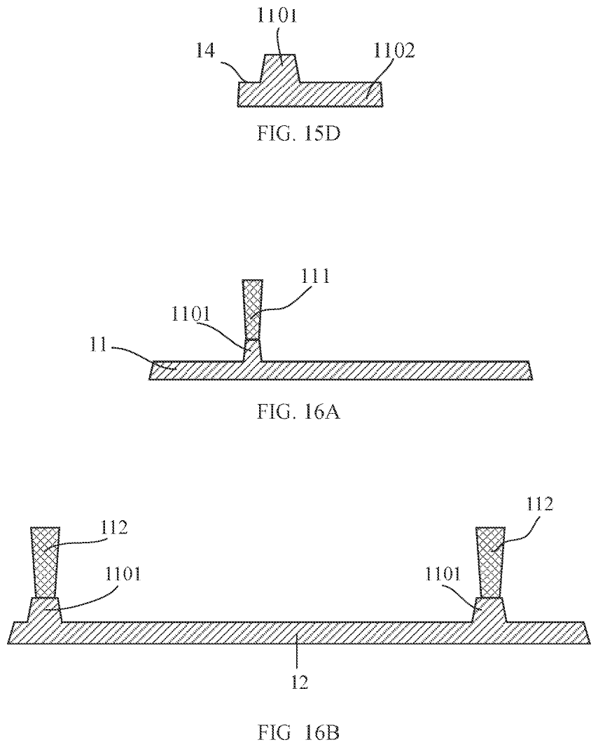

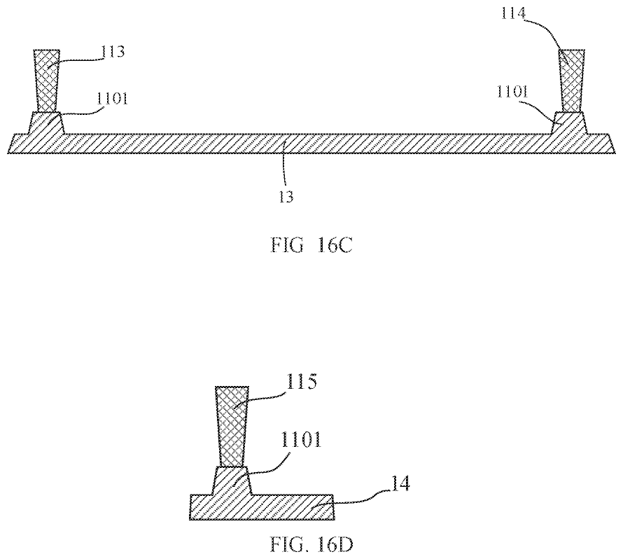

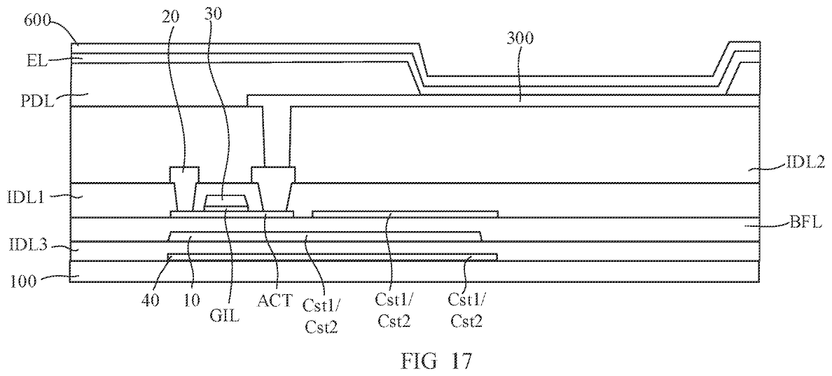

FIGS. 3 to 13 are local plan views of at least one film layer of a display substrate according to some exemplary embodiments of the present disclosure, where FIG. 3 schematically shows a local plan view of a fourth conductive layer of the display substrate, FIG. 4 schematically shows a local plan view of a first conductive layer of the display substrate, FIG. 5 schematically shows a local plan view of a combination of the first conductive layer and the fourth conductive layer of the display substrate, FIG. 6 schematically shows a local plan view of a semiconductor layer of the display substrate, FIG. 7 schematically shows a local plan view of a combination of the fourth conductive layer, the first conductive layer and the semiconductor layer of the display substrate, FIG. 8 schematically shows a local plan view of a third conductive layer of the display substrate, FIG. 9 schematically shows a local plan view of a combination of the fourth conductive layer, the first conductive layer, the semiconductor layer and the third conductive layer of the display substrate, FIG. 10 schematically shows a local plan view of a combination of the fourth conductive layer, the first conductive layer, the semiconductor layer, the third conductive layer and the first insulation layer of the display substrate, FIG. 11 schematically shows a local plan view of a combination of the fourth conductive layer, the first conductive layer, the semiconductor layer, the third conductive layer, the first insulation layer and the second insulation layer of the display substrate, FIG. 12 schematically shows a local plan view of a second conductive layer of the display substrate, and FIG. 13 schematically shows a local plan view of a combination of the fourth conductive layer, the first conductive layer, the semiconductor layer, the third conductive layer, the first insulation layer, the second insulation layer and the second conductive layer of the display substrate. FIG. 14 is a cross-sectional view of a display substrate taken along line AA′ in FIG. 13, according to some exemplary embodiments of the present disclosure. FIGS. 15A to 15D are cross-sectional views of a display substrate taken along lines BB′, CC′, DD′ and EE′ in FIG. 4, respectively, according to some exemplary embodiments of the present disclosure. FIGS. 16A to 16D are cross-sectional views of a display substrate taken along lines FF′, GG′, HH′ and II′ in FIG. 13, respectively, according to some exemplary embodiments of the present disclosure, where only electrical connections between a first conductive layer and a second conductive layer are shown, and other components are omitted. FIG. 17 is a cross-sectional view of a display substrate taken along line JJ′ in FIG. 13, according to some exemplary embodiments of the present disclosure.

Referring to FIGS. 3 to 17, the display substrate may include a plurality of conductive layers, a semiconductor layer, and a plurality of insulation layers. For the convenience of description, the plurality of conductive layers are described as the first conductive layer, the second conductive layer, the third conductive layer, and the fourth conductive layer.

The display substrate may include: a base substrate 100, a fourth conductive layer 40 provided on the base substrate 100, a third insulation layer IDL3 provided on a side of the fourth conductive layer 40 away from the base substrate 100, a first conductive layer 10 provided on a side of the third insulation layer IDL3 away from the base substrate 100, a buffer layer BFL provided on a side of the first conductive layer 10 away from the base substrate 100, a semiconductor layer ACT provided on a side of the buffer layer BFL away from the base substrate 100, a gate insulation layer GIL provided on a side of the semiconductor layer ACT away from the base substrate 100, a third conductive layer 30 provided on a side of the gate insulation layer GIL away from the base substrate 100, a first insulation layer IDL1 provided on a side of the third conductive layer 30 away from the base substrate 100, a second conductive layer 20 provided on a side of the first insulation layer IDL1 away from the base substrate 100, a second insulation layer IDL2 provided on a side of the second conductive layer 20 away from the base substrate 100, a first electrode layer 300 provided on a side of the second insulation layer IDL2 away from the base substrate 100, a pixel defining layer PDL provided on a side of the first electrode layer 300 away from the base substrate 100, a light-emitting material layer EL provided on a side of the pixel defining layer PDL away from the base substrate 100, and a second electrode layer 600 provided on a side of the light-emitting material layer EL away from the base substrate 100.

It will be noted that, the above insulation layers may include a single-layer structure or a stack structure composed of a plurality of insulation layers. For example, the second insulation layer IDL2 may include at least one passivation layer and at least one planarization layer. The specific structure of the insulation layer is not specially limited in the embodiments of the present disclosure.

Referring to FIG. 3, which schematically shows a local plan view of the fourth conductive layer 40, a material of the fourth conductive layer 40 may include a transparent conductive material, such as indium tin oxide (ITO). For example, the first capacitor electrode Cst1 or the second capacitor electrode Cst2 of the storage capacitor Cst may be provided in the first conductive layer 10. In an embodiment of the present disclosure, the display substrate may further include a capacitor wire 5 for electrically connecting the storage capacitor Cst to the sensing transistor T3. Specifically, the capacitor wire 5 may be used for electrically connecting the first capacitor electrode Cst1 or the second capacitor electrode Cst2 of the storage capacitor Cst to one of the source s3 and the drain d3 of the sensing transistor T3. As shown in FIG. 3, the capacitor wire 5 may include a first connection portion 51, a second connection portion 53, and a capacitor wire main body portion 52. The capacitor wire main body portion 52 extends along the second direction Y and is provided between the first connection portion 51 and the second connection portion 53. The first connection portion 51 is connected to the first capacitor electrode Cst1 or the second capacitor electrode Cst2. The second connection portion 53 is electrically connected to one of the source s3 and the drain d3 of the sensing transistor T (which will be described in detail below).

In some exemplary embodiments of the present disclosure, for the same sub-pixel, the first capacitor electrode Cst1 or the second capacitor electrode Cst2 and the capacitor wire 5 form as an integral structure which continuously extends. For example, FIG. 3 schematically shows a local plane view of the fourth conductive layer 40 in four sub-pixels of the same pixel unit. For each sub-pixel, the first capacitor electrode Cst1 or the second capacitor electrode Cst2 has a block pattern with a large area, the capacitor wire 5 has a strip pattern with a large length-width ratio, and the block pattern and the strip pattern are connected to each other, forming an integral structure which continuously extends. In this way, it is beneficial to form the second capacitor electrode and the capacitor wire in the same layer through the same patterning process.

It will be noted that, in this specification, unless otherwise specified, the expression “an integral structure which continuously extends” means that at least two components in the same layer continuously extend without interruption, that is, in the at least two components, at least two ends close to each other are connected to each other.

For the same sub-pixel, an orthographic projection of the first capacitor electrode Cst1 or the second capacitor electrode Cst2 of the pixel driving circuit of the sub-pixel on the base substrate 100 at least partially overlaps with an orthographic projection of the light-emitting region of the sub-pixel on the base substrate 100.

Referring to FIGS. 4 and 5, a material of the first conductive layer 10 may include a light shielding material, such as a metal material. In an embodiment of the present disclosure, the display substrate may further include a first conductive connection portion 11, a second conductive connection portion 12, a third conductive connection portion 13 and a fourth conductive connection portion 14 in the first conductive layer 10. For the same sub-pixel, the first conductive connection portion 11, the second conductive connection portion 12, the third conductive connection portion 13 and the fourth conductive connection portion 14 are spaced apart from each other.

For the same sub-pixel, an orthographic projection of the first conductive connection portion 11 on the base substrate 100 at least partially overlaps with an orthographic projection of the first capacitor electrode Cst1 or the second capacitor electrode Cst2 located in the fourth conductive layer 40 on the base substrate 100. An orthographic projection of the fourth conductive connection portion 14 on the base substrate 100 at least partially overlaps with an orthographic projection of the capacitor wire 5 on the base substrate 100. For example, the orthographic projection of the fourth conductive connection portion 14 on the base substrate 100 at least partially overlaps with an orthographic projection of the second connection portion 53 of the capacitor wire 5 on the base substrate 100. The orthographic projection of each of the second conductive connection portion 12 and the third conductive connection portion 13 on the base substrate 100 does not overlap with the orthographic projection of any of the second capacitor electrode Cst2 and the capacitor wire 5 on the base substrate 100.

In the embodiments of the present disclosure, the display substrate includes a first conductive portion in the first conductive layer 10. The first conductive portion may include at least one of the first conductive connection portion 11, the second conductive connection portion 12, the third conductive connection portion 13 or the fourth conductive connection portion 14. In the following, a structure of the first conductive portion will be further described in conjunction with the accompanying drawings.

It will be noted that, in the embodiments of the present disclosure, the first capacitor electrode Cst1 or the second capacitor electrode Cst2 of the storage capacitor Cst may be provided in the first conductive layer 10. For example, at least a part of the first conductive connection portion 11 may be used as the first capacitor electrode Cst1 or the second capacitor electrode Cst2.

FIG. 6 schematically shows a local plane view of the semiconductor layer ACT. FIG. 7 schematically shows a local plan view of the fourth conductive layer 40, the first conductive layer 10, and the semiconductor layer ACT. In the embodiments of the present disclosure, the semiconductor layer ACT may include various semiconductor materials, such as an amorphous silicon semiconductor material, a polycrystalline silicon semiconductor material, and a metal oxide semiconductor material. Referring to FIGS. 6 and 7, in the embodiments of the present disclosure, the display substrate may further include a first semiconductor portion 301, a second semiconductor portion 302 and a third semiconductor portion 303 which are provided in the semiconductor layer ACT. The first capacitor electrode Cst1 or the second capacitor electrode Cst2 of the storage capacitor Cst may be provided in the semiconductor layer ACT.

It will be noted that, referring to FIGS. 15 and 17, in an embodiment of the present disclosure, one of the first capacitor electrode Cst1 and the second capacitor electrode Cst2 of the storage capacitor Cst may be provided in the first conductive layer 10, for example, may serve as at least a part of the first conductive connection portion 11. The other one of the first capacitor electrode Cst1 and the second capacitor electrode Cst2 of the storage capacitor Cst may be provided in at least one of the fourth conductive layer 40 and the semiconductor layer ACT, For example, the other one of the first capacitor electrode Cst1 and the second capacitor electrode Cst2 may include a block-shaped pattern portion in the fourth conductive layer 40, or, the other one of the first capacitor electrode Cst1 and the second capacitor electrode Cst2 may include a portion of the semiconductor layer ACT transformed into a conductor, or the other one of the first capacitor electrode Cst1 and the second capacitor electrode Cst2 may include both a block-shaped pattern portion in the fourth conductive layer 40 and the portion of the semiconductor layer ACT transformed into a conductor (e.g., a doped semiconductor portion).

For the same sub-pixel, the orthographic projection of the first capacitor electrode Cst1 of the storage capacitor Cst on the base substrate 100 at least partially overlaps with the orthographic projection of the second capacitor electrode Cst2 of the storage capacitor Cst on the base substrate 100. In this way, the first capacitor electrode Cst1 and the second capacitor electrode Cst2 are arranged opposite to each other to form the storage capacitor Cst.

For example, the first semiconductor portion 301 corresponds to the driving transistor T1. The first semiconductor portion 301 may include a source region 301s, a drain region 301d, and a channel region 301c. The channel region 301c is a channel region of the driving transistor T1, and the source region 301s and the drain region 301d correspond to the source s1 and the drain d1 of the driving transistor T1, respectively. It will be understood that the channel region may have semiconductor characteristics. The source and drain regions may be semiconductor portions subjected to a conductor transformation treatment, such as doped semiconductor portions.

For example, the second semiconductor portion 302 corresponds to the switching transistor T2. The second semiconductor portion 302 may include a source region 302s, a drain region 302d, and a channel region 302c. The channel region 302c is a channel region of the switching transistor T2. The source region 302s and the drain region 302d correspond to the source s2 and the drain d2 of the switching transistor T2, respectively.

For example, the third semiconductor portion 303 corresponds to the sensing transistor T3. The third semiconductor portion 303 may include a source region 303s, a drain region 303d, and a channel region 303c. The channel region 303c is a channel region of the sensing transistor T3. The source region 303s and the drain region 303d correspond to the source s3 and the drain d3 of the sensing transistor T3, respectively.

In some exemplary embodiments of the present disclosure, for the same sub-pixel, an orthographic projection of the first semiconductor portion 301 on the base substrate 100 at least partially overlaps with the orthographic projection of the first conductive connection portion 11 on the base substrate 100, and the orthographic projection of the first semiconductor portion 301 on the base substrate 100 at least partially overlaps with the orthographic projection of the first capacitor electrode Cst1 on the base substrate 100 or the orthographic projection of the second capacitor electrode Cst2 on the base substrate 100. For example, for the same sub-pixel, the orthographic projection of the first semiconductor portion 301 on the base substrate 100 falls within the orthographic projection of the first conductive connection portion 11 on the base substrate 100, and the orthographic projection of the first semiconductor portion 301 on the base substrate 100 falls within the orthographic projection of the first capacitor electrode Cst1 on the base substrate 100 or the orthographic projection of the second capacitor electrode Cst2 on the base substrate 100.

In some exemplary embodiments of the present disclosure, for the same sub-pixel, an orthographic projection of the third semiconductor portion 303 on the base substrate 100 at least partially overlaps with an orthographic projection of the second conductive connection portion 12 on the base substrate 100, and the orthographic projection of the third semiconductor portion 303 on the base substrate 100 at least partially overlaps with the orthographic projection of the fourth conductive connection portion 14 on the base substrate 100. For example, for the same sub-pixel, an orthographic projection of one end of the third semiconductor portion 303 on the base substrate 100 at least partially overlaps with the orthographic projection of the second conductive connection portion 12 on the base substrate 100, and an orthographic projection of the other end of the third semiconductor portion 303 on the base substrate 100 at least partially overlaps with the orthographic projection of the fourth conductive connection portion 14 on the base substrate 100.

FIG. 8 schematically shows a local plan view of the third conductive layer 30. FIG. 9 schematically shows a local plan view of the fourth conductive layer 40, the first conductive layer 10, the semiconductor layer ACT, and the third conductive layer 30. In the embodiments of the present disclosure, the third conductive layer 30 may include various gate materials. Referring to FIGS. 8 and 9, in the embodiments of the present disclosure, the display substrate may further include a first gate conductor portion 31, a second gate conductor portion 32, a first auxiliary wire 33, a second auxiliary wire 34 and a third auxiliary wire 35 that are all located in the third conductive layer 30. The display substrate may further include a first scanning signal line GL1 and a second scanning signal line GL2 for supplying gate scanning signals, both of which are located in the third conductive layer 30.

For example, the first gate conductor portion 31 corresponds to the driving transistor T1. An orthographic projection of the first gate conductor portion 31 on the base substrate 100 at least partially overlaps with an orthographic projection of the first semiconductor portion 301 (such as the channel region 301c of the driving transistor T1) on the base substrate 100. The part of the first gate conductor portion 31 overlapping with the channel region 301c of the driving transistor T1 serves as the gate g1 of the driving transistor T1.

For example, the first scanning signal line GL1 corresponds to the switching transistor T2. An orthographic projection of the first scanning signal line GL1 on the base substrate 100 at least partially overlaps with an orthographic projection of the second semiconductor portion 302 (such as the channel region 302c of the switching transistor T2) on the base substrate 100. The part of the first scanning signal line GL1 overlapping with the channel region 302c of the switching transistor T2 serves as the gate g2 of the switching transistor T2. For example, the first scanning signal line GL1 includes a protruding portion protruding along the second direction Y, and the protruding portion is the second gate conductor portion 32 mentioned above. In the embodiments of the present disclosure, the first scanning signal line GL1 is below the channel region 302c of the switching transistor T2 in the second direction Y, and the second gate conductor portion 32 of the first scanning signal line GL1 extends upwards towards the channel region 302c of the switching transistor T2.

For example, the second scanning signal line GL2 corresponds to the sensing transistor T3. An orthographic projection of the second scanning signal line GL2 on the base substrate 100 at least partially overlaps with an orthographic projection of the third semiconductor portion 303 (such as the channel region 303c of the sensing transistor T3) on the base substrate 100. The part of the second scanning signal line GL2 overlapping with the channel region 303c of the sensing transistor T3 serves as the gate g3 of the sensing transistor T3.

In the embodiments of the present disclosure, the first scanning signal line GL1 and the second scanning signal line GL2 substantially extend along the first direction X. The first auxiliary wire 33, the second auxiliary wire 34 and the third auxiliary wire 35 substantially extend along the second direction Y.

In the embodiments of the present disclosure, the first scanning signal line GL1 and the second scanning signal line GL2, which are used to supply the gate scanning signals to the pixel driving circuits of the sub-pixels in the same row, are respectively located on opposite sides of the light-emitting regions of the sub-pixels in the same row in the second direction Y. For example, in the illustrated embodiment, the first scanning signal line GL1 and the second scanning signal line GL2, which are used to supply the gate scanning signals to the pixel driving circuits of the sub-pixels in the same row, are respectively located on the upper and lower sides of the light-emitting regions of the sub-pixels in the same row in the second direction Y.

FIG. 10 schematically shows a local plan view of a combination of the fourth conductive layer, the first conductive layer, the semiconductor layer, the third conductive layer and the first insulation layer of the display substrate, and some via holes in the first insulation layer IDL1 are schematically shown in FIG. 10.

Referring to FIG. 10, the display substrate may include a first conductive via hole VH1 passing through the first insulation layer IDL1. The first conductive via hole VH1 exposes a part of the first conductive connection portion 11. The first conductive via hole VH1 exposes at least a part of a first conductive sub-portion 1101 of the first conductive connection portion 11. The first conductive via hole VH1 exposes the first source region 301s or the first drain region 301d of the driving transistor T1.

The display substrate may include a second conductive via hole VH2 passing through the first insulation layer IDL1. The second conductive via hole VH2 exposes a part of the second conductive connection portion 12. The second conductive via hole VH2 exposes at least a part of a first conductive sub-portion 1101 of the second conductive connection portion 12. The second conductive via hole VH2 exposes the third source region 303s or the third drain region 303d of the sensing transistor T3.

The display substrate may include a third conductive via hole VH3 passing through the first insulation layer IDL1. The third conductive via hole VH3 exposes a part of the third conductive connection portion 13. The third conductive via hole VH3 exposes at least a part of a first conductive sub-portion 1101 of the third conductive connection portion 13.

The display substrate may include a fourth conductive via hole VH4 passing through the first insulation layer IDL1. The fourth conductive via hole VH4 exposes another part of the third conductive connection portion 13. The fourth conductive via hole VH4 exposes at least a part of the first conductive sub-portion 1101 of the fourth conductive via hole VH4.

The display substrate may include a fifth conductive via hole VH5 passing through the first insulation layer IDL1. The fifth conductive via hole VH5 exposes a part of the fourth conductive connection portion 14. The fifth conductive via hole VH5 exposes at least a part of a first conductive sub-portion 1101 of the fourth conductive connection portion 14. The fifth conductive via hole VH5 exposes the third drain region 303d or the third source region 303s of the sensing transistor T3.

FIG. 11 schematically shows a local plan view of the second conductive layer 20. FIG. 12 schematically shows a local plan view of the fourth conductive layer 40, the first conductive layer 10, the semiconductor layer ACT, the third conductive layer 30, the first insulation layer IDL1, and the second conductive layer 20. In the embodiments of the present disclosure, the second conductive layer 20 may include various source and drain materials. Referring to FIGS. 11 and 12, in the embodiments of the present disclosure, the display substrate may further include a first power signal line VDD, a data line DL, a sensing signal line SL, a first conductive transfer portion 21, a second conductive transfer portion 22, a third conductive transfer portion 23, a fourth conductive transfer portion 24, a fifth conductive transfer portion 25 and a sixth conductive transfer portion 26, which are all located in the second conductive layer 20. For the same sub-pixel, the first power signal line VDD, the data line DL, the sensing signal line SL, the first conductive transfer portion 21, the second conductive transfer portion 22, the fourth conductive transfer portion 24, the fifth conductive transfer portion 25 and the sixth conductive transfer portion 26 are spaced apart from each other. The third conductive transfer portion 23 is a part of the first power signal line VDD.

Referring to FIGS. 3 to 17, the display substrate includes a first conductive portion 110 in the first conductive layer 10 and a second conductive portion 120 in the second conductive layer 20. An orthographic projection of the first conductive portion 110 on the base substrate 100 at least partially overlaps with an orthographic projection of the second conductive portion 120 on the base substrate 100.

For example, the first conductive portion 110 may be at least one of the first conductive connection portion 11, the second conductive connection portion 12, the third conductive connection portion 13 or the fourth conductive connection portion 14. The second conductive portion 120 may be at least one of the first conductive transfer portion 21, the second conductive transfer portion 22, the third conductive transfer portion 23, the fourth conductive transfer portion 24 or the fifth conductive transfer portion 25.

The display substrate further includes at least one conductive via hole VH. The at least one conductive via hole passes through at least the first insulation layer IDL1. For example, the at least one conductive via hole VH may be at least one of the first conductive via hole VH1, the second conductive via hole VH2, the third conductive via hole VH3, the fourth conductive via hole VH4 or the fifth conductive via hole VH5 mentioned above.

The display substrate may further include at least one conductive plug 1110 located in the at least one conductive via hole VH. The second conductive portion 120 is electrically connected to the first conductive portion 110 through the at least one conductive plug 1110. The “conductive plug” will be further described in the following in conjunction with the accompanying drawings.

Referring to FIG. 14, the first conductive portion 110 may include a first conductive sub-portion 1101 and a second conductive sub-portion 1102, an orthographic projection of the first conductive sub-portion 1101 on the base substrate at least partially overlaps with an orthographic projection of the at least one conductive via hole VH on the base substrate. A thickness of the first conductive sub-portion 1101 in a third direction Z is greater than a thickness of the second conductive sub-portion 1102 in the third direction Z, and the third direction Z is perpendicular to a plane defined by the first direction X and the second direction Y. That is to say, the first conductive sub-portion is the part of the first conductive portion corresponding to the conductive via hole, and the second conductive sub-portion is the remaining part of the first conductive portion other than the first conductive sub-portion. In the embodiments of the present disclosure, the thickness of the first conductive sub-portion is greater than the thickness of the second conductive sub-portion.

The first conductive sub-portion 1101 includes a first top surface 1101T away from the base substrate 100, the second conductive sub-portion 1102 includes a second top surface 1102T away from the base substrate 100, and the first top surface 1101T is further away from the base substrate 100 than the second top surface 1102T in the third direction Z.

Referring to FIG. 14, the first conductive sub-portion 1101 includes a protruding portion, the protruding portion protrudes towards the at least one conductive via hole VH relative to the second top surface 1102T of the second conductive sub-portion 1102, and the at least one conductive plug 1110 is in contact with at least a part of the first top surface 1101T of the first conductive sub-portion.

The buffer layer BFL exposes at least a part of the first conductive sub-portion 1101. The buffer layer BFL covers the second conductive sub-portion 1102. Specifically, the buffer layer BFL includes a third top surface BFLT away from the base substrate 100, and the first top surface 1101T of the first conductive sub-portion 1101 is substantially flush with a part of the third top surface BFLT adjacent to the first conductive sub-portion 1101.

It will be noted that, unless otherwise specified, in the present disclosure, the expression “be substantially flush with” means that the two objects being compared are at the same height in the third direction Z, or they are in the same horizontal plane; alternatively, there may be some height difference between the two objects being compared in the third direction Z, but such height difference is within ±5 of a thickness of the main components to which the two objects belong. For example, here, that the first top surface 1101T is substantially flush with the third top surface BFLT may include: the first top surface 1101T and the third top surface BFLT are at the same height in the third direction Z, or the height difference between the first top surface 1101T and the third top surface BFLT is within ±5 of a thickness of the first conductive portion 110 or a thickness of the buffer layer BFL.

Referring to FIG. 14, the protruding portion includes a first side surface 11011 and a second side surface 11012, the first side surface 11011 and the second side surface 11012 are on opposite sides of the first top surface 1101T, and the first side surface 11011 and the second side surface 11012 is connected through the first top surface 1101T. The buffer layer BFL is in contact with and covers the second top surface 1102T of the second conductive sub-portion 1102, the first side surface 11011, and the second side surface 11012.

The first conductive sub-portion 1101 includes a first bottom surface 1101B proximate to the base substrate 100, the second conductive sub-portion 1102 includes a second bottom surface 1102B proximate to the base substrate 100, and the first bottom surface 1101B is substantially flush with the second bottom surface 1102B in the third direction Z. For example, here, that the first bottom surface 1101B is substantially flush with the second bottom surface 1102B may include: the first bottom surface 1101B and the second bottom surface 1102B are at the same height in the third direction Z, or the height difference between the first bottom surface 1101B and the second bottom surface 1102B is within ±5 of the thickness of the first conductive portion 110 or the thickness of the buffer layer BFL.

Referring to FIG. 14, the second conductive portion 120 includes a third bottom surface 120B proximate to the base substrate 100; at a position adjacent to the at least one conductive via hole VH, the third bottom surface 120B of the second conductive portion is spaced apart from the second top surface 1102T of the second conductive sub-portion 1102 by a first distance H1 in the third direction Z, and a depth H2 of the at least one conductive via hole VH in the third direction Z is less than the first distance H1.

Referring to FIGS. 1 to 17, in some embodiments, the first conductive portion 110 may include the first conductive connection portion 11 in the first conductive layer 10. That is, the first conductive connection portion 11 may include a first conductive sub-portion 1101 and a second conductive sub-portion 1102, and a thickness of the first conductive sub-portion 1101 of the first conductive connection portion 11 along the third direction Z is greater than a thickness of the second conductive sub-portion 1102 of the first conductive connection portion 11 along the third direction Z.

It will be noted that, as the first conductive connection portion 11 is a specific implementation of the first conductive portion 110 mentioned above, the above description of the first conductive portion may be applied to the first conductive connection portion 11 here. The specific structure of the first conductive connection portion 11, especially its cross-sectional structure, may be referred to the description above.

The second conductive portion 120 may include the first conductive transfer portion 21 in the second conductive layer 20. An orthographic projection of the first conductive transfer portion 21 on the base substrate falls within an orthographic projection of the first conductive connection portion 11 on the base substrate.

In this embodiment, the at least one conductive via hole VH includes the first conductive via hole VH1, the at least one conductive plug 1110 includes the first conductive plug 111, and the first conductive plug 111 is arranged in the first conductive via hole VH1. The orthographic projection of the first conductive transfer portion 21 on the base substrate at least partially overlaps with an orthographic projection of the first conductive via hole VH1 on the base substrate. For example, the orthographic projection of the first conductive transfer portion 21 on the base substrate 100 may cover the orthographic projection of the first conductive via hole VH1 on the base substrate 100. An orthographic projection of a part of the first conductive via hole VH1 on the base substrate at least partially overlaps with an orthographic projection of the first conductive sub-portion 1101 of the first conductive connection portion 11 on the base substrate, one end of the first conductive plug 111 is electrically connected to the first conductive sub-portion 1101 of the first conductive connection portion 11, and the other end of the first conductive plug 11 is electrically connected to the first conductive transfer portion 21.

The orthographic projection of the first conductive via hole VH1 on the base substrate at least partially overlaps with an orthographic projection of one of the first source region 301s and the first drain region 301d on the base substrate. One of the first source region 301s and the first drain region 301d is electrically connected to the first conductive transfer portion 21 through the first conductive via hole VH1.

An electrical connection between the source s1 or the drain d1 of the driving transistor T1 and the first capacitor electrode Cst1 or the second capacitor electrode Cst2 may be achieved through transfer conductive structures such as the first conductive connection portion 11, the first conductive via hole VH1 and the first conductive transfer portion 21.

In some embodiments, the first conductive portion 110 may include the second conductive connection portion 12 in the first conductive layer 10. For example, the second conductive connection portion 11 may include two first conductive sub-portions 1101 and one second conductive sub-portion 1102. A thickness of the first conductive sub-portion 1101 of the second conductive connection portion 12 along the third direction Z is greater than a thickness of the second conductive sub-portion 1102 of the second conductive connection portion 12 along the third direction Z.

It will be noted that, as the second conductive connection portion 12 is a specific implementation of the first conductive portion 110 mentioned above, the above description of the first conductive portion may be applied to the second conductive connection portion 12 here. The specific structure of the second conductive connection portion 12, especially its cross-sectional structure, may be referred to the description above.

In an embodiment of the present disclosure, the second conductive connection portion 12 is electrically connected to the sensing signal line SL.

An orthographic projection of the second conductive transfer portion 22 on the base substrate at least partially overlaps with an orthographic projection of the second conductive connection portion 12 on the base substrate.

The at least one conductive via hole VH includes the second conductive via hole VH2, the at least one conductive plug 1110 includes a second conductive plug 112, and the second conductive plug 112 is arranged in the second conductive via hole VH2.

The orthographic projection of the second conductive transfer portion 22 on the base substrate at least partially overlaps with an orthographic projection of the second conductive via hole VH2 on the base substrate.

An orthographic projection of a part of the second conductive via hole VH2 on the base substrate at least partially overlaps with an orthographic projection of the first conductive sub-portion 1101 of the second conductive connection portion 12 on the base substrate, one end of the second conductive plug 112 is electrically connected to the first conductive sub-portion 1101 of the second conductive connection portion 12, and the other end of the second conductive plug 112 is electrically connected to the second conductive transfer portion 22.

The orthographic projection of the second conductive via hole VH2 on the base substrate at least partially overlaps with an orthographic projection of one of the third source region 303s and the third drain region 303d on the base substrate, and the one of the third source region 303s and the third drain region 303d is electrically connected to the second conductive transfer portion 22 through the second conductive via hole VH2.

In some embodiments, the first conductive portion 110 may include a third conductive connection portion 13 in the first conductive layer 10. For example, one third conductive connection portion 13 may include two first conductive sub-portions 1101 and one second conductive sub-portion 1102. A thickness of the first conductive sub-portion 1101 of the third conductive connection portion 13 along the third direction Z is greater than a thickness of the second conductive sub-portion 1102 of the third conductive connection portion 13 along the third direction Z.

It will be noted that, as the third conductive connection portion 13 is a specific implementation of the first conductive portion 110 mentioned above, the above description of the first conductive portion may be applied to the third conductive connection portion 13 here. The specific structure of the third conductive connection portion 13, especially its cross-sectional structure, may be referred to the description above.

In an embodiment of the present disclosure, the third conductive connection portion 23 is a part of the first power signal line VDD. An orthographic projection of the third conductive transfer portion 23 on the base substrate at least partially overlaps with an orthographic projection of the third conductive connection portion 13 on the base substrate.

At least one conductive via hole VH includes the third conductive via hole VH3, the at least one conductive plug 1110 includes a third conductive plug 113, and the third conductive plug 113 is arranged in the third conductive via hole VH3.

An orthographic projection of the first power signal line VDD on the base substrate at least partially overlaps with an orthographic projection of the third conductive via hole VH3 on the base substrate.

One third conductive connection portion 13 includes two first conductive sub-portions 1101, the orthographic projection of the third conductive via hole VH3 on the base substrate at least partially overlaps with an orthographic projection of one of the two first conductive sub-portions 1101 of the third conductive connection portion 13 on the base substrate, one end of the third conductive plug 113 is electrically connected to the one of the two first conductive sub-portions 1101 of the third conductive connection portion 13, and the other end of the third conductive plug 113 is electrically connected to the first power signal line VDD.

An orthographic projection of the fourth conductive transfer portion 24 on the base substrate at least partially overlaps with the orthographic projection of the third conductive connection portion 13 on the base substrate.

The at least one conductive via hole VH includes the fourth conductive via hole VH4, the at least one conductive plug 1110 includes a fourth conductive plug 114, and the fourth conductive plug 114 is arranged in the fourth conductive via hole VH4.

The orthographic projection of the fourth conductive transfer portion 24 on the base substrate at least partially overlaps with an orthographic projection of the fourth conductive via hole VH4 on the base substrate.

The orthographic projection of the fourth conductive via hole VH4 on the base substrate at least partially overlaps with an orthographic projection of the other one of the two first conductive sub-portions 1101 of the third conductive connection portion 13 on the base substrate, one end of the fourth conductive plug 114 is electrically connected to the other one of the two first conductive sub-portions 1101 of the third conductive connection portion 13, and the other end of the fourth conductive plug 114 is electrically connected to the fourth conductive transfer portion 24.

In some embodiments, the first conductive portion 110 may include the fourth conductive connection portion 14 in the first conductive layer 10. For example, one fourth conductive connection portion 14 may include one first conductive sub-portion 1101 and one second conductive sub-portion 1102. A thickness of the first conductive sub-portion 1101 of the fourth conductive connection portion 14 along the third direction Z is greater than a thickness of the second conductive sub-portion 1102 of the fourth conductive connection portion 14 along the third direction Z.

It will be noted that, as the fourth conductive connection portion 14 is a specific implementation of the first conductive portion 110 mentioned above, the above description of the first conductive portion may be applied to the fourth conductive connection portion 14 here. The specific structure of the fourth conductive connection portion 14, especially its cross-sectional structure, may be referred to the description above.

In the embodiments of the present disclosure, an orthographic projection of the fifth conductive transfer portion 25 on the base substrate at least partially overlaps with an orthographic projection of the fourth conductive connection portion 14 on the base substrate.

At least one conductive via hole VH includes the fifth conductive via hole VH5, the at least one conductive plug 1110 includes a fifth conductive plug 115, and the fifth conductive plug 115 is arranged in the fifth conductive via hole VH5.

The orthographic projection of the fifth conductive transfer portion 25 on the base substrate at least partially overlaps with an orthographic projection of the fifth conductive via hole VH5 on the base substrate.

The orthographic projection of the fifth conductive via hole VH5 on the base substrate at least partially overlaps with an orthographic projection of the first conductive sub-portion 1101 of the fourth conductive connection portion 14 on the base substrate, one end of the fifth conductive plug 115 is electrically connected to the first conductive sub-portion 1101 of the fourth conductive connection portion 14, and the other end of the fifth conductive plug 115 is electrically connected to the fifth conductive transfer portion 25.

The orthographic projection of the fifth conductive via hole VH5 on the base substrate at least partially overlaps with an orthographic projection of the other one of the third source region 303s and the third drain region 303d on the base substrate, and the other one of the third source region 303s and the third drain region 303d is electrically connected to the fifth conductive transfer portion 25 through the fifth conductive via hole VH5.

In the embodiments of the present disclosure, an orthographic projection of the fifth conductive transfer portion 25 on the base substrate 100 at least partially overlaps with an orthographic projection of the fifth conductive via hole VH5 on the base substrate 100. For example, the orthographic projection of the fifth conductive transfer portion 25 on the base substrate 100 may cover the orthographic projection of the fifth conductive via hole VH5 on the base substrate 100. An electrical connection between the source s3 or the drain d3 of the sensing transistor T3 and the capacitor wire 5 may be achieved through transfer conductive structures such as the fourth conductive connection portion 14, the fifth conductive via hole VH5, and the fifth conductive transfer portion 25.

In the embodiments of the present disclosure, an orthographic projection of the sixth conductive transfer portion 26 on the base substrate 100 at least partially overlaps with an orthographic projection of the seventh via hole VH7 on the base substrate 100. For example, the orthographic projection of the sixth conductive transfer portion 26 on the base substrate 100 may cover the orthographic projection of the seventh via hole VH7 on the base substrate 100. An electrical connection between the gate g1 of the driving transistor T1 and the second capacitor electrode Cst2 or the first capacitor electrode Cst1 may be achieved through transfer conductive structures such as the seventh via hole VH7 and the sixth conductive transfer portion 26.

For example, the first power signal line VDD may be electrically connected to the source region s1 or the drain region d1 of the driving transistor T1 through the eighth via hole VH8.

For example, in the embodiments of the present disclosure, for the same sub-pixel, an orthographic projection of the data line DL on the base substrate 100 at least partially overlaps with an orthographic projection of the first auxiliary wire 33 on the base substrate 100. For example, the orthographic projection of the data line DL on the base substrate 100 covers the orthographic projection of the first auxiliary wire 33 on the base substrate 100. The data line DL may be electrically connected to the first auxiliary wire 33 through a tenth via hole VH10. For example, a plurality of tenth via holes VH10 may be arranged at intervals along the second direction Y, and the data line DL may be electrically connected to the first auxiliary wire 33 through the plurality of tenth via holes VH10 arranged at intervals. In this way, the contact area between the data line DL and the first auxiliary wire 33 may be increased, thereby reducing a contact resistance and reducing a voltage drop on the data line DL.

In the embodiments of the present disclosure, for the same sub-pixel, the orthographic projection of the first auxiliary wire 33, which is electrically connected to the data line for applying data signals to the pixel driving circuit of the sub-pixel, on the base substrate 100 and the orthographic projection of the capacitor wire main body portion 52 of the pixel driving circuit of the sub-pixel on the base substrate 100 are spaced from each other.

For example, in the embodiments of the present disclosure, for the same sub-pixel, the orthographic projection of the sensing signal line SL on the base substrate 100 at least partially overlaps with the orthographic projection of the second auxiliary wire 34 on the base substrate 100. For example, the orthographic projection of the sensing signal line SL on the base substrate 100 covers the orthographic projection of the second auxiliary wire 34 on the base substrate 100. The sensing signal line SL may be electrically connected to the second auxiliary wire 34 through an eleventh via hole VH11. For example, a plurality of eleventh via holes VH11 may be arranged at intervals along the second direction Y, and the sensing signal line SL may be electrically connected to the first auxiliary wire 33 through plurality of eleventh via holes VH11 arranged at intervals. In this way, the contact area between the sensing signal line SL and the second auxiliary wire 34 may be increased, thereby reducing a contact resistance and reducing a voltage drop on the sensing signal line SL.

For example, in the embodiments of the present disclosure, for the same sub-pixel, the orthographic projection of the first power signal line VDD on the base substrate 100 at least partially overlaps with the orthographic projection of the third auxiliary wire 35 on the base substrate 100. For example, the orthographic projection of the first power signal line VDD on the base substrate 100 covers the orthographic projection of the third auxiliary wire 35 on the base substrate 100. The first power signal line VDD may be electrically connected to the third auxiliary wire 35 through a twelfth via hole VH12. For example, a plurality of twelfth via holes VH12 may be arranged at intervals along the second direction Y, and the first power signal line VDD may be electrically connected to the first auxiliary wire 33 through the plurality of twelfth via holes VH12 arranged at intervals. In this way, the contact area between the first power signal line VDD and the first auxiliary wire 33 may be increased, thereby reducing a contact resistance and reducing a voltage drop on the first power signal line VDD.

For example, the data line DL may be electrically connected to the source region s2 or the drain region d2 of the switching transistor T2 through a ninth via hole VH9.

In the embodiments of the present disclosure, two data lines DL are provided between two sub-pixels adjacent to each other in the same row. For example, the two sub-pixels adjacent to each other in the same row include a first sub-pixel SP1 and a second sub-pixel SP2, and the two data lines include a first data line DL1 and a second data line DL2.

The first data line DL1 is used to supply a data signal to the first sub-pixel SP1. An orthographic projection of a data line main body portion of the data line DL1, which is used to supply the data signal to the pixel driving circuit of the first sub-pixel, on the base substrate is spaced apart from an orthographic projection of the capacitor wire main body portion 52 in the pixel driving circuit of the first sub-pixel on the base substrate.

The second data line DL2 is used to supply a data signal to the second sub-pixel SP2. An orthographic projection of a data line main body portion of the data line DL2, which is used to supply the data signal to the pixel driving circuit of the second sub-pixel, on the base substrate is spaced apart from an orthographic projection of the capacitor wire main body portion 52 in the pixel driving circuit of the second sub-pixel on the base substrate.

For example, the sensing signal line SL includes a first part SL1 extending along the second direction Y and a second part SL2 extending along the first direction X. In the first direction X, the second sub-pixel SP2 is adjacent to the sensing signal line SL, and the first sub-pixel SP1 is on a side of the second sub-pixel SP2 away from the sensing signal line SL.

For example, one end of the second conductive connection portion 12 is electrically connected to the other one of the source s3 and the drain d3 of the sensing transistor T3 of the pixel driving circuit of the first sub-pixel SP1 through the second conductive via hole VH2. The other end of the second conductive connection portion 12 is electrically connected to the other one of the source s3 and the drain d3 of the sensing transistor T3 of the pixel driving circuit of the second sub-pixel SP2 through the sixth via hole VH6.

The second part SL2 of the sensing signal line is electrically connected to the other end of the second conductive connection portion 12 and the other one of the source s3 and the drain d3 of the sensing transistor T3 in the pixel driving circuit of the second sub-pixel SP2 through the sixth via hole VH6. In this way, a sensing signal supplied by the sensing signal line SL may be transmitted to each of the sub-pixels of the pixel unit.

For example, the first power signal line VDD is on a side of the first sub-pixel SP1 away from the second sub-pixel SP2. The first power signal line VDD may be electrically connected to the source s1 or the drain d1 of the driving transistor T1 through the third conductive via hole VH3, the third conductive connection portion 13, the fourth conductive via hole VH4 and the fourth conductive transfer portion 24.

In the embodiments of the present disclosure, referring to FIGS. 14 and 17, the pixel defining layer PDL includes a plurality of openings 80 for defining the light-emitting regions SPA1, SPA2, SPA3 and SPA4 in the plurality of sub-pixels.

The embodiments of the present disclosure further provide a display apparatus, which may include the display substrate mentioned above. The display apparatus may include but not limited to any product or component with a display function, such as an electronic paper, mobile phone, tablet, TV, monitor, laptop, digital photo frame, navigation device, etc. It will be understood that the beneficial effect of the display apparatus is the same as that of the display substrate provided in the above embodiments.

Although some embodiments of the overall concept of the present disclosure have been illustrated and described, those skilled in the art will understand that changes may be made to these embodiments without departing from the principles and spirit of the overall invention concept of the present disclosure. The scope of the present disclosure is defined by the claims and their equivalents.

1. A display substrate, comprising:
a base substrate;
a plurality of pixel units provided on the base substrate, wherein the plurality of pixel units are arranged in an array in a first direction and a second direction, and at least one of the plurality of pixel units comprises a plurality of sub-pixels, at least one of the plurality of sub-pixels comprises a light-emitting element and a pixel driving circuit configured to drive the light-emitting element, the first direction intersecting with the second direction;
a first conductive layer provided on the base substrate;
a buffer layer provided on a side of the first conductive layer away from the base substrate;
a semiconductor layer provided on a side of the buffer layer away from the base substrate;
a first insulation layer provided on a side of the semiconductor layer away from the base substrate; and
a second conductive layer provided on a side of the first insulation layer away from the base substrate,
wherein the pixel driving circuit comprises at least one transistor and a storage capacitor, the at least one transistor comprises a source and a drain, the storage capacitor comprises a first capacitor electrode and a second capacitor electrode opposite to each other, one of the first capacitor electrode and the second capacitor electrode is in the first conductive layer, and the source and the drain of the at least one transistor are in the second conductive layer;
wherein the display substrate comprises a first conductive portion in the first conductive layer and a second conductive portion in the second conductive layer, and an orthographic projection of the first conductive portion on the base substrate at least partially overlaps with an orthographic projection of the second conductive portion on the base substrate;
wherein the display substrate further comprises at least one conductive via hole and at least one conductive plug in the at least one conductive via hole, the at least one conductive via hole passing through at least the first insulation layer, and the second conductive portion is electrically connected to the first conductive portion through the at least one conductive plug; and
wherein the first conductive portion comprises a first conductive sub-portion and a second conductive sub-portion, an orthographic projection of the first conductive sub-portion on the base substrate at least partially overlaps with an orthographic projection of the at least one conductive via hole on the base substrate, and a thickness of the first conductive sub-portion in a third direction is greater than a thickness of the second conductive sub-portion in the third direction, the third direction being perpendicular to a plane defined by the first direction and the second direction.

2. The display substrate according to claim 1, wherein the first conductive sub-portion comprises a first top surface away from the base substrate, the second conductive sub-portion comprises a second top surface away from the base substrate, and the first top surface is further away from the base substrate than the second top surface in the third direction.

3. The display substrate according to claim 2, wherein the first conductive sub-portion comprises a protruding portion, the protruding portion protrudes towards the at least one conductive via hole relative to the second top surface of the second conductive sub-portion, and the at least one conductive plug is in contact with at least a part of the first top surface of the first conductive sub-portion.

4. The display substrate according to claim 1, wherein:
the buffer layer exposes at least a part of the first conductive sub-portion; and/or
the buffer layer covers the second conductive sub-portion.

5. The display substrate according to claim 2, wherein the buffer layer comprises a third top surface away from the base substrate, and the first top surface of the first conductive sub-portion is substantially flush with a part of the third top surface adjacent to the first conductive sub-portion.

6. The display substrate according to claim 4, wherein:
the protruding portion comprises a first side surface and a second side surface, the first side surface and the second side surface are on opposite sides of the first top surface, and the first side surface and the second side surface is connected through the first top surface; and
the buffer layer is in contact with a second top surface of the second conductive sub-portion, the first side surface and the second side surface, and the buffer layer covers the second top surface of the second conductive sub-portion, the first side surface and the second side surface.

7. The display substrate according to claim 5, wherein the first conductive sub-portion comprises a first bottom surface proximate to the base substrate, the second conductive sub-portion comprises a second bottom surface proximate to the base substrate, and the first bottom surface is substantially flush with the second bottom surface in the third direction.

8. The display substrate according to claim 7, wherein the second conductive portion comprises a third bottom surface proximate to the base substrate; at a position adjacent to the at least one conductive via hole, the third bottom surface of the second conductive portion is spaced apart from the second top surface of the second conductive sub-portion by a first distance in the third direction, and a depth of the at least one conductive via hole in the third direction is less than the first distance.

9. The display substrate according to claim 1, wherein:
the first conductive portion comprises a first conductive connection portion in the first conductive layer, and at least a part of the first conductive connection portion serves as the second capacitor electrode;
the second conductive portion comprises a first conductive transfer portion in the second conductive layer; and
an orthographic projection of the first conductive transfer portion on the base substrate falls within an orthographic projection of the first conductive connection portion on the base substrate.

10. The display substrate according to claim 9, wherein
the at least one conductive via hole comprises a first conductive via hole, and the at least one conductive plug comprises a first conductive plug in the first conductive via hole;
the orthographic projection of the first conductive transfer portion on the base substrate at least partially overlaps with an orthographic projection of the first conductive via hole on the base substrate; and
an orthographic projection of a part of the first conductive via hole on the base substrate at least partially overlaps with an orthographic projection of a first conductive sub-portion of the first conductive connection portion on the base substrate, one end of the first conductive plug is electrically connected to the first conductive sub-portion of the first conductive connection portion, and the other end of the first conductive plug is electrically connected to the first conductive transfer portion.

11. The display substrate according to claim 10, wherein
the at least one transistor comprises a driving transistor, and the driving transistor comprises a channel region;
the display substrate further comprises a first semiconductor portion in the semiconductor layer, the first semiconductor portion comprises a first source region, a first drain region and the channel region of the driving transistor, and the first source region and the first drain region are on opposite sides of the channel region of the driving transistor, respectively;
the orthographic projection of the first conductive via hole on the base substrate at least partially overlaps with an orthographic projection of one of the first source region and the first drain region on the base substrate; and
the one of the first source region and the first drain region is electrically connected to the first conductive transfer portion through the first conductive via hole.

12. The display substrate according to claim 11, wherein
the first conductive portion comprises a second conductive connection portion in the first conductive layer, the display substrate further comprises a sensing signal line, and the second conductive connection portion is electrically connected to the sensing signal line;
the second conductive portion comprises a second conductive transfer portion in the second conductive layer; and
an orthographic projection of the second conductive transfer portion on the base substrate at least partially overlaps with an orthographic projection of the second conductive connection portion on the base substrate.

13. The display substrate according to claim 12, wherein
the at least one conductive via hole comprises a second conductive via hole, and the at least one conductive plug comprises a second conductive plug in the second conductive via hole;
the orthographic projection of the second conductive transfer portion on the base substrate at least partially overlaps with an orthographic projection of the second conductive via hole on the base substrate; and
an orthographic projection of a part of the second conductive via hole on the base substrate at least partially overlaps with an orthographic projection of a first conductive sub-portion of the second conductive connection portion on the base substrate, one end of the second conductive plug is electrically connected to the first conductive sub-portion of the second conductive connection portion, and the other end of the second conductive plug is electrically connected to the second conductive transfer portion.

14. The display substrate according to claim 13, wherein
the at least one transistor comprises a sensing transistor, and the sensing transistor comprises a channel region;
the display substrate further comprises a third semiconductor portion in the semiconductor layer, the third semiconductor portion comprises a third source region, a third drain region and the channel region of the sensing transistor, and the third source region and the third drain region are on opposite sides of the channel region of the sensing transistor, respectively;
the orthographic projection of the second conductive via hole on the base substrate at least partially overlaps with an orthographic projection of one of the third source region and the third drain region on the base substrate; and
the one of the third source region and the third drain region is electrically connected to the second conductive transfer portion through the second conductive via hole.

15. The display substrate according to claim 14, wherein
the first conductive portion comprises a third conductive connection portion in the first conductive layer;
the second conductive portion comprises a third conductive transfer portion in the second conductive layer, the display substrate comprises a first power signal line in the second conductive layer, and the third conductive connection portion is a part of the first power signal line; and
an orthographic projection of the third conductive transfer portion on the base substrate at least partially overlaps with an orthographic projection of the third conductive connection portion on the base substrate.

16. The display substrate according to claim 15, wherein
the at least one conductive via hole comprises a third conductive via hole, and the at least one conductive plug comprises a third conductive plug in the third conductive via hole;
an orthographic projection of the first power signal line on the base substrate at least partially overlaps with an orthographic projection of the third conductive via hole on the base substrate; and
the third conductive connection portion comprises two first conductive sub-portions, the orthographic projection of the third conductive via hole on the base substrate at least partially overlaps with an orthographic projection of one of the two first conductive sub-portions of the third conductive connection portion on the base substrate, one end of the third conductive plug is electrically connected to the one of the two first conductive sub-portions of the third conductive connection portion, and the other end of the third conductive plug is electrically connected to the first power signal line.

17. The display substrate according to claim 16, wherein
the second conductive portion further comprises a fourth conductive transfer portion in the second conductive layer; and
an orthographic projection of the fourth conductive transfer portion on the base substrate at least partially overlaps with the orthographic projection of the third conductive connection portion on the base substrate.

18. The display substrate according to claim 17, wherein;
the at least one conductive via hole comprises a fourth conductive via hole, and the at least one conductive plug comprises a fourth conductive plug in the fourth conductive via hole;
the orthographic projection of the fourth conductive transfer portion on the base substrate at least partially overlaps with an orthographic projection of the fourth conductive via hole on the base substrate;
the orthographic projection of the fourth conductive via hole on the base substrate at least partially overlaps with an orthographic projection of the other one of the two first conductive sub-portions of the third conductive connection portion on the base substrate, one end of the fourth conductive plug is electrically connected to the other one of the two first conductive sub-portions of the third conductive connection portion, and the other end of the fourth conductive plug is electrically connected to the fourth conductive transfer portion;
the first conductive portion comprises a fourth conductive connection portion in the first conductive layer;
the second conductive portion comprises a fifth conductive transfer portion in the second conductive layer;
an orthographic projection of the fifth conductive transfer portion on the base substrate at least partially overlaps with an orthographic projection of the fourth conductive connection portion on the base substrate;
the at least one conductive via hole comprises a fifth conductive via hole, and the at least one conductive plug comprises a fifth conductive plug in the fifth conductive via hole;
the orthographic projection of the fifth conductive transfer portion on the base substrate at least partially overlaps with an orthographic projection of the fifth conductive via hole on the base substrate;
the orthographic projection of the fifth conductive via hole on the base substrate at least partially overlaps with an orthographic projection of a first conductive sub-portion of the fourth conductive connection portion on the base substrate, one end of the fifth conductive plug is electrically connected to the first conductive sub-portion of the fourth conductive connection portion, and the other end of the fifth conductive plug is electrically connected to the fifth conductive transfer portion;
the orthographic projection of the fifth conductive via hole on the base substrate at least partially overlaps with an orthographic projection of the other one of the third source region and the third drain region on the base substrate; and
the other one of the third source region and the third drain region is electrically connected to the fifth conductive transfer portion through the fifth conductive via hole.

19-21. (canceled)

22. A display apparatus, comprising the display substrate according to claim 1.

23. A method for manufacturing a display substrate, comprising:
forming a first conductive material layer on a base substrate;
patterning the first conductive material layer using a halftone mask process to form a first conductive layer comprising a first conductive portion, wherein the first conductive portion comprises a first conductive sub-portion and a second conductive sub-portion;
forming a buffer material layer on a side of the first conductive layer away from the base substrate;
patterning the buffer material layer using a mask process to form a buffer layer;
forming a semiconductor material layer on a side of the buffer layer away from the base substrate;
patterning the semiconductor material layer using a mask process to form a semiconductor layer;
forming a first insulation material layer on a side of the semiconductor layer away from the base substrate;
patterning the first insulation material layer using a mask process to form a first insulation layer comprising at least one conductive via hole, wherein the at least one conductive via hole passes through at least the first insulation layer;
forming a second conductive material layer on a side of the first insulation layer away from the base substrate, wherein at least a part of the second conductive material layer is formed in the at least one conductive via hole to form at least one conductive plug in the at least one conductive via hole; and
patterning the second conductive material layer using a mask process to form a second conductive layer comprising a second conductive portion, wherein an orthographic projection of the first conductive portion on the base substrate at least partially overlaps with an orthographic projection of the second conductive portion on the base substrate, and the second conductive portion is electrically connected to the first conductive portion through the at least one conductive plug,
wherein an orthographic projection of the first conductive sub-portion on the base substrate at least partially overlaps with an orthographic projection of the at least one conductive via hole on the base substrate, and a thickness of the first conductive sub-portion in a third direction is greater than a thickness of the second conductive sub-portion in the third direction, the third direction being perpendicular to a surface of the base substrate proximate to the first conductive layer.
